(19) United States
(12) Patent Application Publication
(10) Pub. No.: US 2022/0380890 A1
(43) Pub. Date: Dec. 1, 2022

(54) Method for Processing Flexible Substrates and Vacuum Processing System for Implementing the Method

(71) Applicant: elfolion GMBH, Quedlinburg (DE)

(72) Inventor: MANFRED DANZIGER, Quedlinburg (DE)

(21) Appl. No.: 17/755,925

(22) PCT Filed: Nov. 7, 2020
(86) PCT No.: PCT/DE2020/000274

§ 371 Date: May 11, 2022

(30) Foreign Application Priority Data
Nov. 14, 2019 (DE) 10 2019 007 935.3

(51) Int. Cl. C23C 14/56; C23C 4/137; C23C 4/14

(52) U.S. Cl. CPC C23C 14/562; C23C 4/137; C23C 4/14

(57) ABSTRACT

Processing a flexible substrate of a matrix-shaped or lattice-shaped construction material. A first layer thereof is transported in a first transport direction, and a second layer thereof is transported in parallel with and closely spaced apart from the first layer in an opposite, second transport direction through a free region in the evacuable process area. A usable flux of a processing instrument penetrates the first and the second layer of the flexible substrate simultaneously while transported through the free region in an opposite direction. Also, a vacuum processing system including two roller groups, each group including smaller and larger rollers deflecting the flexible substrate. The free region including a processing instrument arranged between the roller groups through which the flexible substrate is transported in an opposite direction and without directional change. At least two closely spaced apart layers of the flexible substrate are transported in opposite directions.

The invention relates to a method for processing flexible substrates, in which a flexible substrate for processing with a processing instrument is moved through an evacuable process area of a vacuum processing system.

The invention also relates to a vacuum processing system for implementing the method for processing flexible substrates, the vacuum processing system having at least one unwind module, one take-up module and an evacuable process area arranged between these modules with one or more processing instruments.

The invention relates in particular to the interaction of a vacuum processing system and its optimization for processing flexible film-like substrates, which are characterized by a very high proportion of free, open volume.

Flexible substrates in a so-called strip form or strip-shaped substrates can consist of a wide variety of materials, such as plastics, metals, paper and textiles. Such flexible strip-shaped substrates are usually wound onto a roll, also known as a coil, and are therefore referred to as a winding or as a spool. For processing, the flexible strip-shaped substrates are unwound from a first coil, which is mounted on an unwinding device or an unwind module, processed in the evacuable process area of a vacuum processing system, which can include one or more connected modules, and then wound up again on another roll, which is stored on a winding device or a take-up module.

Such a device is referred to in its entirety as a “reel-to-reel” system or as a “reel-to-reel” winding device or as a “reel-to-reel” conveyor system. If the system is used in vacuum technology, it is referred to as a modular “reel-to-reel” vacuum processing system. If coating processes are carried out in the modular process areas of the “reel-to-reel” system, this is referred to as “reel-to-reel” vacuum coating systems.

Typically, several different processing steps are required to process a flexible substrate in strip form. The requirements resulting from the respective physical and/or chemical process conditions in a processing area can differ completely from module to module of the vacuum processing system.

Physical and/or chemical process conditions are in particular pressure, temperature, amount of gas flux, type and composition of the gas in the processing area of the flexible substrate as well as the physical or chemical mode of action of the processing media, also called processing instruments or processing tools or processing aggregates, which are used to process the strip material, mostly for processing or coating its surfaces. These process requirements and process conditions also result in the need to use a modular design of the “reel-to-reel” vacuum coating system.

For a modular vacuum processing system, there are effective methods of practically preventing pressure equalization or gas exchange between the individual modules or chambers of the vacuum processing system. Therefore, for many applications there is a requirement to install devices with a lock function as connecting devices between the individual modules or chambers, and the unwinding device and take-up device are also regarded as modules in this frame of reference, which although largely preventing pressure equalization and/or gas exchange, however allowing the transport of the flexible strip-shaped substrate. This does not completely prevent gas exchange or pressure equalization between adjacent spaces such as the modules or chambers, but it is considerably restricted, and usually even minimized to the point of being almost totally eliminated.

Locks that prevent pressure equalization or gas exchange between the individual modules or chambers or chamber sections as far as possible, can be used as lock assemblies or as so-called lock chambers in modular vacuum coating systems.

A lock assembly embodies so-called roller locks. With roller locks, two rollers are pressed together with a preset force. The rollers rotate in the opposite direction and are mostly not driven. It is advantageous to apply an additional supporting force to the rollers for their rotary movement. The rollers are inserted in a housing that allows a connection path between the two adjacent chambers of a vacuum processing system only between the rollers. Such rollers are usually coated with a material that prevents the surface of the flexible strip-shaped substrate from being affected at all or only insignificantly.

WO 001999050472 A1 discloses a lock assembly which is referred to as a roller lock and consists of two rollers in a first embodiment. In this arrangement, a first and a second roller are arranged prestressed in order to generate a contact pressure between the two rollers, thus achieving a very good seal between the two adjacent chambers in whose connecting area the pair of lock rollers is integrated. Sealing components are arranged in the area of the walls, with the side of these components facing the respective roller having a cylindrical shape. It is intended that the gap is kept as small as technically and technologically possible so as to prevent as much as possible pressure equalization and gas exchange.

An alternative variant is also described in WO 001999050472 A1. This roller lock consists of a roller, which faces two corresponding sealing components, whereby the strip-shaped flexible material on the roller surface is transported through the gap between the roller and a sealing component from one chamber into a second.

So-called slit locks represent another type of lock. The strip material is guided through the slit locks hanging unsupported. In the case of strip materials, the gap width, i.e. the distance between the top and bottom of the space that is spanned by the slit lock and through which the strip material is pulled, is no greater than ten times the thickness of the strip material. Preferred are ranges within two to three times the thickness of the strip material. The length of such slit locks is usually between 10 and 40 cm.

If the gas exchange and thus pressure equalization is to be prevented particularly effectively and/or if the working pressure in the adjacent modules or chambers differs by more than one order of magnitude, then it is known to use so-called lock chambers to decouple the individual volumes of the system. A lock chamber offers the possibility of a separate pump-out connection to which a pump or a pump system can be connected, whereby different pressure conditions or gas feeds can be implemented in the two modules or chambers adjacent to the lock chamber.

DE 102005042762 A1 describes a vacuum coating system for the continuous coating of a film. The vacuum coating system includes a single vacuum chamber with a coating roller. The interior of the vacuum chamber is separated by partitions into various sub-chambers, which thereby assume a modular function. The sub-chambers can be evacuated by independent vacuum pumps. When transporting the film material through the sub-chambers, the film surface can be coated using vacuum technology methods.

WO 2019/141303 A1 describes film-like functional materials that fulfill at least one predetermined function and can be used for specific physical, chemical, physicochemical, biological or other technical or technological purposes.

These functional materials consist of at least one construction material, which is arranged as a film-like carrier medium having a total carrier volume and having a cross-sectional dimension of ≤100 μm.

Film-like materials are, like foils, thin materials in sheet or web form with a large extent in two dimensions and a comparatively small extent in a third dimension.

The difference between sheet-like materials and foils is that the body of a sheet-like material that is characterized by x, y and z, where x and y characterize the areal extent of the body and z is the direction of the cross-sectional extent, i.e. the measurable distance from a side of the body to the opposite side of the body, and Δx indicate the length, Δy the width and Δz the cross-sectional extent of the sheet-like material, is within this dimension coherently filled with a material while not filling the entire space, i.e. the material from which the foil-like material is made does not completely macroscopically fill the three-dimensional space spanned by this body.

In the case considered in the present invention, the volume of the free space is at least as large as the volume occupied by the structural elements of the structural material. Typically, however, the volume of the free space is even larger, in certain cases even much larger.

The construction material is to be regarded as a matrix or as a lattice and is composed of line-shaped and node-shaped carrier elements, which form the material components of the carrier medium and penetrate the total volume of the carrier, to form a ribbon-shaped extension with interconnected sub-volumes of the total volume of the carrier located therein, which are spanned by neighboring carrier elements.

Such matrix- or lattice-shaped materials are becoming increasingly important for use as a constructive component in functional materials. Functional materials of this type are distinguished, for example, by their electrical, magnetic, optical, acoustic, biological-chemical or other properties. These matrix- or lattice-shaped construction materials often represent the starting material for further processing into functional materials. These matrix- or lattice-shaped construction materials which are typically characterized by their special mechanical properties such as their rigidity or strength, their density, their hardness or their resistance to wear, and are typically composed of thermally stable base materials such as glass or high-temperature plastics. Such high-temperature plastics are, for example, aramids, polyimides (PI), polyaryletherketone (PEAK), polyetheretherketone (PEEK), polytetrafluoroethylene (PTFE) or other thermally stable plastics.

However, the matrix- or lattice-shaped construction materials can also be made of other materials, such as metals, commonly referred to as metal wire, such as copper wire, aluminum wire, steel wire, metal alloy wire or metal-coated metal wire, or mineral fibers, for example rock wool fibers.

According to the state of the art, not all areas of such construction materials which are constructed like a matrix or a lattice can disadvantageously not be sufficiently reliably and effectively processed or machined. This effect is especially noticeable in coating processes. This means that effective process control is usually not possible and the quality of the coating is subject to strong fluctuations.

Thus, there is a need for methods of processing flexible substrates and vacuum processing equipment for implementing such methods for processing flexible substrates that overcome the disadvantages known from the prior art.

The invention is based on the object of specifying a method for processing flexible substrates and a vacuum processing system for implementing the method for processing flexible substrates, which enable reliable processing with adequate quality that is uniform in all areas of a flexible matrix- or lattice-shaped substrate, in particular when carrying out a coating process. The solution of this object is particularly important when performing vacuum coating processes.

In particular, the processing of foil-like, flexible, matrix- or lattice-shaped materials, which are a starting material or intermediate stages in the processing of the material in terms of the production of a functional material, is to be improved.

The object is achieved by a method for processing flexible substrates with the features according to patent claim 1 of the independent patent claims. Further developments are recited in the dependent patent claims.

The object is achieved by a vacuum processing system for implementing the method for processing flexible substrates with the features according to patent claim 11 of the independent patent claims. Further developments are recited in the dependent patent claims.

In the following, the term flexible, matrix- or lattice-shaped material is to be used both for a so-called starting material and for materials in all intermediate processing stages of a manufacturing process.

The starting materials are in particular matrix- or lattice-shaped construction materials composed of a plurality of individual carrier elements. Here, the carrier elements are line-shaped and hence large in a first dimension and small in a second and third dimension. These carrier elements can also be node-shaped. A first dimension may be, for example, an extent in an x-direction, with an extent in a second dimension being a y-direction and an extent in a third dimension being a z-direction. In this case, the x-direction may correspond to the transport direction of the flexible, matrix- or lattice-shaped construction material.

Such line-shaped carrier elements are carrier elements that have approximately the same dimensions in the two dimensions that are the small dimensions of the line-shaped carrier element. These two small dimensions of the line-shaped carrier element may be, for example, the y-direction and the z-direction.

The ratio of the large first dimension (x-direction) to the two smaller second and third dimensions (y-direction, z-direction) is at least a ratio of 50:1. For example, the extent of the carrier element in the first dimension may be 50 times greater than an extent of the carrier element in its second and third dimension.

The ratio of the extents of the two smaller second and third dimensions to one another is, for example, not less than 1:5 and not greater than 5:1. Thus, the extent of the third dimension is, for example, in a range between 5 times as large as the second dimension and 5 times smaller than the second dimension.

In the case of large distances between the line-shaped carrier elements, at least in some sections, the illustrated limitations of the line-shaped carrier elements may also be exceeded. The line-shaped carrier elements are at least in sections spaced from one another by large distances, so that the proportion of the areal effect of the line-shaped carrier elements in relation to the geometric plane in which the surfaces of the line-shaped carrier elements are located is practically negligible, so that the line-shaped carrier elements do not cause an almost complete delimitation of the spanned partial volumes from each other.

The carrier elements, which penetrate the total carrier volume, are thus arranged in sections spaced apart from one another in such a way that partial volumes are spanned between neighboring carrier elements. The spanned sub-volumes are formed as open, interconnected free spaces or voids.

In particular, the total volume of the free partial volumes within the construction material is not smaller than the total volume occupied by the carrier elements. The ratio of the total volume of the free partial volumes to the total volume occupied by the carrier elements is preferably at least 2:1 or at least 5:1, particularly preferably at least 10:1.

In simplified terms, a construction material of this type can be described as a matrix or lattice that spans a band-shaped structure that is traversed at different angles by a few line-shaped carrier elements in relation to a removed unit area that is located in the plane of the band, wherein the carrier elements can cross and thereby form a node, i.e. a node-shaped carrier element, or meet in a node-shaped carrier structure. The remaining volume, which is located within the strip-shaped matrix, represents a void in the context of vacuum processing.

If the matrix- or lattice-shaped construction material is viewed from the top side or bottom side of the strip, the property of the structure becomes visible, namely that is has more empty space than space that is filled with solids.

This consideration is necessary if the matrix- or lattice-shaped construction material is to be processed on the top or bottom. The proportion of solid components in the matrix- or lattice construction material is so low that a conventional processing method for this type of material proves to be highly ineffective.

The situation is of even more concern when the solid elements, i.e. the line-shaped and node-shaped carrier elements, are to be coated with a material to be deposited. The coating unit, which is arranged above and/or below the band-shaped structure, faces only a few surfaces of the solid elements of the matrix- or lattice-shaped construction material, on which material can be deposited by the operation of the coating units.

According to the invention, a first layer of the flexible substrate or the matrix- or lattice-shaped construction material is transported in a first transport direction and at least one second layer of the flexible substrate is transported parallel or at least quasi-parallel to the first layer of the flexible substrate and closely spaced from the first layer in a second transport direction opposite to the first transport direction through a first free region in the evacuatable process area. Preferably, more layers, for example four or six layers, are also transported, closely spaced from one another and preferably parallel to one another, in mutually opposite directions through the evacuatable process area in which at least one process source is arranged. If the strip-shaped structure of the flexible substrate or the matrix- or lattice-shaped construction material is traversed by a particularly small number of line-shaped carrier elements in relation to a removed unit area located in the strip plane, then the number of layers transported in opposite directions through the evacuatable process area in which at least one process source is arranged, may be even higher than six, in certain cases even significantly higher. For example, up to 15 layers may be transported in opposite directions through the evacuatable process area.

In an alternative embodiment, a first layer of the flexible substrate may be transported in a first transport direction through a first free region and subsequently in a third transport direction different from the first transport direction through a second free region. The flexible substrate is then deflected and transported in at least a second layer closely spaced and preferably parallel to the first layer in a fourth transport direction opposite to the third transport direction through the second free region and subsequently in a second transport direction opposite to the first transport direction through the first free region in the evacuatable process area. Moreover, at least one process source configured to process the matrix- or lattice-shaped construction material may be arranged in the free regions. In this alternative design, too, up to 15 layers may be transported in opposite directions through the free regions.

Furthermore, a first group of rollers and a second group of rollers may be arranged in a vacuum processing system, with several rollers having a smaller diameter and several rollers having a larger diameter, hereinafter referred to as smaller and larger rollers, being arranged in each roller group for deflecting the flexible substrate. A free region with at least one processing instrument, through which the flexible substrate is transported in opposite directions and without a change in direction, is arranged between the first group of rollers and the second group of rollers.

In this case, the roller groups are arranged in such a way that the flexible substrate is transported in at least two opposite, preferably mutually parallel layers, in a first transport direction and a second transport direction.

Alternatively, a first group of rollers, a second group of rollers and a third group of rollers may be arranged, wherein a second free region is arranged between the first group of rollers and the third group of rollers and a third free region is arranged between the second group of rollers and the third group of rollers, with the groups of rollers being arranged in such a way that the flexible substrate is transported in at least two mutually parallel layers through the second free region and the third free region. At least one processing instrument is arranged in the first and/or in the second free region, with the flexible substrate being transported through the free regions in opposite directions and without a change in direction.

The transport direction of the flexible substrate through the second free region may be at an angle to the transport direction of the flexible substrate through the third free region.

The vacuum processing system described here for processing flexible substrates and the associated process provide the following possibilities and advantages:
The surface of the elements to be processed, i.e. the line-shaped and node-shaped carrier elements, may be prepared for a subsequent coating with the aid of surface processing, such as ion or ion beam etching.
The line-shaped and node-shaped carrier elements may be provided with an enveloping coating, i.e. the line-shaped and node-shaped carrier elements are completely covered with the material to be coated.
Furthermore, the voids between the line-shaped and node-shaped carrier elements may be partially or completely filled with materials based on special vacuum coating processes.
Layers may be built up on special areas of the line-shaped carrier elements, for example on their inner edges and on areas of the node-shaped carrier elements, which are already provided with an enveloping coating made of the same coating material or of a different material, which layers may be used to cover the voids of the matrix- or lattice-shaped construction material or the flexible substrate.
In addition, the surface of the deposited materials may be suitably functionalized, for example by using an ion treatment.

The special feature, which is reflected in particular in the unique characteristic of the structural composition of the aforedescribed matrix- or lattice-shaped construction material, requires a significant change in the processing technology compared to conventional film processing in vacuum chambers or in vacuum systems in order to enable effective processing.

Various types of processing and different processing tasks must be considered, which lead to mutually different solutions, sometimes significantly solutions, for the design and equipment within the vacuum system.

For the description, the following considerations should be mentioned at the beginning:

Various physical quantities that result from the product of a field and an area are referred to as flux Φ. The scalar flux of a vector field, i.e. the scalar product of the vector field and the area, is of practical importance. Important scalar fluxes of vector fields are, for example, the volume flux, the magnetic flux and the electric flux. In simplified terms, the flux φ can be thought of as the number of particles, mass, energy, and so on, moving through an area per unit of time. This state of the art can be found, for example, under the link: https://de.wikipedia.org/wiki/Fluss_(Physik).

It is also known that current is generally defined as a quantity passing through a given cross-sectional area per unit of time, i.e. as:

dQ/dt, (1)

wherein Q here refers to a quantity. If the quantity exemplifies an energy, then the current corresponds to a power. A current is therefore a special flux that is characterized by the fact that a quantifiable quantity is transported.

The electric current or the current strength of the charge Q_{charge} during a certain unit of time t is also a flux Φ, namely the flux of the current density Φ_{current density}:

$${Φ}_{current density} = {\int }_{A} \vec{J} * d \vec{A} = \frac{d Q}{dt} = I \qquad ( 2 )$$

wherein \vec{J} is the vector field current flux density and \vec{A} the normal area.

Further examples are the volume flux, i.e. the volume per unit of time, the mass flux, i.e. the—weight-based—mass per unit of time, the particle flux, i.e. the number of particles per unit of time, such as sputtered particles in a vacuum coating process, the radiation flux, i.e. the electromagnetic radiation per unit of time, or the luminous flux, i.e. light or photons per unit of time. This prior art can be found, for example, under the link: https://www.chemie.de/lexikon/Fluss_(Physik).html.

In contrast to the particle flux, no material is transported in an electric flux. Although the electric flux has mathematical properties similar to those of a real flux in a flux field, for example, it does not transport anything material, such as charge carriers, but merely transmits the action of the underlying force field from one point to another.

In the case of surface processing technology in vacuum systems to be considered here, the flux Φ includes all processes, i.e. both the material, e.g. particle transport, and the immaterial transport, e.g. the propagation of a field.

The basic idea is that the matrix or lattice-like construction materials are influenced by the effect of a flux Φ in a configuration where they are positioned on top of one another at a small distance from one another and move against one another, i.e. in a meandering manner. Flux represents a current or a propagating field whose source is a processing instrument.

The flux Φ is emitted through an area, the so-called flux exit area, of the processing medium into space, i.e. into the vacuum chamber.

The flux can within the space in which the flux spreads produce an effect by interacting with matter. In a technical application in vacuum processing systems, the effect represents a deliberate effect on a solid, i.e. its surface or the area close to the surface. The effect that can be achieved by the flux Φ decreases as the emitted field moves away from the processing instrument. In technical applications, the range of the flux Φ is limited, which of course is an arbitrary procedure. The limitation means that the spatial extent of the flux Φ is only to be understood as having at each location within this area, which is defined by the coordinates x, y and z, the intensity of the effect I_{effect} at the respective location

I(x,y,z)=I_{effect}±ΔI (3)

wherein I_{effect} is the average effect of the flux Φ emitted from a surface of the processing medium on a surface or near-surface area of a solid, and ΔI represents the maximum magnitude of the effect by which the average effect may be less or greater. This area of the flux Φ is called the usable flux Φ_{usable}. In vacuum technology, the terms processing or process space are often used instead of the term usable flux.

The top side and bottom side of the matrix- or lattice-shaped construction materials span a surface and should in this context also be viewed as a surface. Due to the small proportion of surface area that the surface proportion of the carrier elements occupies in relation to the total area of the usable flux Φ_{usable}, which is emitted through a surface of the processing medium, the probability that the carrier elements of the individual layers of the matrix- or lattice-shaped construction material cover or overlap one another in the area in which these opposing layers can move, is low or extremely low.

This also means that the more layers of a matrix- or lattice-shaped construction material are located on top of one another, the more is the field of view filled with solid surface proportions of the carrier elements when looking at the top side or bottom side of the matrix- or lattice-shaped construction material. The effect is also amplified when the superimposed layers move in opposite directions, further reducing the likelihood of a sustained overlap.

This effect also means that the number of superimposed layers in the processing area may be further increased in such case.

In any case, however, the smaller the surface proportion of the carrier elements of the matrix- or lattice-shaped construction material is in relation to the surface that can be seen from the top side or bottom side of the band-shaped structure, the more layers can be arranged one on top of the other when taking into account that the process runs efficiently and effectively.

On this basis, surface treatment processes of the carrier elements can be implemented much more effectively, because due to the layer formation of the matrix- or lattice-shaped construction material much more solid material than in the case where a single layer is transported through this area is located in the usable flux Φ, i.e. in the spatial area in which the field or the current generated by the processing instrument unfolds its usable effect.

According to the present invention, a device such as a vacuum processing system is provided for processing flexible matrix- or lattice-shaped substrates, with the device having an unwind module and a take-up module for the flexible substrate, devices for processing and means for guiding the flexible substrate from the unwind module to the take-up module.

In particular, the flexible matrix- or lattice-shaped substrate to be processed has a structure which results from a few line-shaped and node-shaped carrier elements running through the structure and a residual volume region which is located inside the substrate and represents a void.

The vacuum processing system has a modular structure with a module disposed between the unwinding and take-up module or several adjacent modules through which the flexible matrix- or lattice-shaped substrate, which is also referred to as winding material, is transported.

The residual gas pressure in a processing chamber or in a process space of the vacuum processing system should generally be below 10⁻⁴ mbar, but must in any case meet the process conditions, so that it can also be less than or greater than 10⁻⁴ mbar. In the case of machining processes, it can be significantly higher when a process gas is intentionally admitted.

Various types of vacuum processing units or process sources can be used as the processing medium, also referred to as processing or process sources, with which surface processing steps, such as pretreatment, cleaning, drying, surface activation and/or polymerization of the substrate and coatings for further processing, can be performed. Typical process sources in surface treatment are, for example, various and diverse electron sources, ion sources or special laser devices. Process sources are devices usually used for physical or chemical coating. The physical coating is called Physical Vapor Deposition (PVD) and the chemical coating Chemical Vapor Deposition (CVD). Typical sources are, for example, sputter sources, in particular magnetron sputter sources, vapor deposition, plasma physical vapor deposition or chemical vapor deposition sources (PVD or CVD sources), which are available in a large number of different device types and devices. These process sources can also be used with limitations for pre-treatment, cleaning, drying, surface activation and/or polymerization of the construction material.

Another form of coating is thermal spraying under vacuum conditions. Thermal vacuum spraying is understood to include all technically possible variants of thermal spraying that can be used under vacuum conditions. The most common form is vacuum arc spraying.

One object of vacuum processing the aforedescribed matrix- or lattice-shaped construction materials is to either process the surfaces of the line-shaped and node-shaped carrier elements, for example when the construction material is the starting material for further processing, or to coat them with one or more substances. Quite often, this substance or these substances may be applied as an enveloping coating of the line-shaped and node-shaped carrier elements, whereby the matrix or lattice shape of the coated construction material should be retained, i.e. the free, interconnected sub-volumes continue to exist in the carrier medium, whereas the substance or the substances enveloping the volume of the carrier elements are reduced.

In order to be able to solve these tasks effectively, it is proposed in an inventive solution that the strip-shaped construction material is transported several times at a small distance from one another, for example in a meandering shape, through the usable flux Φ_{usable} or through the processing space or through the processing space in which the processing process with at least one process source is effective.

For example, in the case of ion processing of the surface of the matrix- or lattice-shaped construction material, the effect of the energetic ions is almost identical within the usable flux, i.e. ΔI from equation (3) is a negligible quantity. For a coating process, the deposition rate, i.e. the amount of material during the time interval when a defined section/area of the material to be coated is in the process space, is almost the same for any section/area of a layer of the matrix- or lattice-shaped construction material that has left the process space. The fact that the winding material, i.e. the construction material, moves back and forth several times through the processing space in close proximity from one another ensures that relatively uniform processing is achieved after the matrix- or lattice-type construction material has finally left the processing space.

This processing method can be implemented by guiding the winding material, i.e. the construction material, over corresponding deflection rollers so that it traverses the processing space several times and the distance between the layers of construction material moving in opposite directions is dimensioned to be as small as technically possible.

The process space, in which, as already explained, a comparable effective intensity can be achieved, is often characterized in that its depth, which is to be understood as the length perpendicular to the strip plane or to the transport direction of the construction material, is not a large value, i.e. the dimension of the process space is relatively small. This circumstance is due to the mean free path of the effective particles, i.e. the magnitude of the length that a particle (e.g. atom, molecule, ion or electron) travels on average in a given material before it collides in some way with another particle. For this reason, the distance between the individual winding material layers of the construction material, whose adjacent layers always move in opposite directions, must often be kept as small as possible, i.e. as small as technical and technological conditions allow.

It is therefore planned to integrate a winding system into the vacuum coating system that allows the condition of the small distance between the individual layers of the matrix- or lattice-shaped construction material moving in opposite directions.

This winding system and the processing space are designed in such a way that the employed matrix- or lattice-shaped construction material is able to withstand the thermal stress caused by a processing process and is not deformed outside of permissible limits or even destroyed.

It is therefore provided to use deflection rollers that invert the direction of movement of the transport of the construction material or reverse its direction.

Furthermore, these deflection rollers may be equipped with or connected to a cooling device in order to ensure that at least part of the energy introduced by processing the line-shaped and node-shaped carrier elements can be dissipated.

Another object of vacuum processing the aforedescribed matrix- or lattice-shaped construction materials is to fill the voids that are spanned by the line-shaped and node-shaped carrier elements or by line-shaped and node-shaped carrier elements that have already been coated with a material, with another material that is used for coating, so that the free space area or the empty space of the strip-shaped matrix- or lattice-shaped construction material is filled with this additional material, whereby the filling procedure is to be understood as “introducing” the material into the empty space of the matrix.

This also means that filling with this additional material does not necessarily have to cover the entire volume, but rather, and this fact represents the general case, that the separated additional material was distributed within the entire free space area, but this does not mean a filling covering the entire volume. In other words, the further material introduced into the free space areas can be characterized in that it embodies a porous, generally an open porous structure.

For this purpose, the winding material, i.e. the construction material, is guided several times through the process space or through the usable flux Φ_{usable} within the process space, the propagating field or the current emitted by the process source. The winding material is pulled through its processing field at an acute angle to the basic direction of action of the flux Φ_{usable}. To increase the effect of the processing process, the winding material is moved through the processing field in a meandering manner, so that the winding material is moved into the acute angle both in the effective direction of the flux and against it, with the winding material also being transported at the acute angle.

For the majority of process sources, the effect that is to be viewed as an interaction is characterized by a preferred direction. This means that the flux basically spreads out in a specific, predetermined direction. This direction is referred to as basic flux direction or primary direction. Although the main part of the interaction is effective in the predetermined direction, effects also take place within an angular distribution, i.e. the effect is distributed over different directions in space, which may also be viewed as scattering of the angular distribution of the effect.

In ion processing, for example, the interaction is an interaction between the energetic ions and the surface of the medium to be processed, such as the construction material, with the ions moving in a preferred, predetermined direction. For example, collisions with neutral particles or interactions with like-charged particles result in an angular distribution of the moving ions, which is noticeable during surface treatment.

In this case, too, an angular distribution of the effect can be observed. In the case of a coating, the movement of the particles of the material to be deposited also runs in a preferred, a predetermined direction, which represents the basic direction of flux for the coating process. In coating processes, this direction is determined by the thermal conditions. The flux Φ_{usable} and its preferred direction always spreads from the energetically highest state, i.e. from the emitting surface of the processing medium or the process source, through which the material to be deposited, for example the material to be evaporated or the evaporated particles, which is/are generated in the processing instrument, i.e. from the area that has the highest temperature to the energetically lowest state, i.e. to the area in which the lowest temperatures are present.

The substrate to be coated, like the construction material, should therefore have the lowest energy state. Collisions with other neutral particles, for example with gas atoms, or if present also with charged particles or with photons, result in an angular distribution of the particles that are deposited on the surface of the substrate and thus in turn represent an angular distribution of the effect.

Moreover, the existing free space area of the matrix- or lattice-shaped construction material, which is used as the winding material and is spanned by the line-shaped and node-shaped carrier elements or by line-shaped and node-shaped carrier elements already coated with a material in a covering manner, may also be closed with a material over an area, but not by filling the entire volume, without the requirement that the area-covering material layer represents a completely closed covering layer, but rather may have a porosity, advantageously for many applications an open porosity.

For many applications, the porosity of the deposited layers is a very important requirement. It is therefore only important that the deposited layer covers the free space area of the construction material, namely in the sense of a covering cladding. It is also quite possible for the layer covering the free space area to consist of several components which, taken together, cause the free space area to be completely covered. This layer does not have to completely enclose the carrier elements or envelope the carrier elements that have already been coated, but may be built up, for example, on a partial area of the carrier elements, for example the inner edge of the line-shaped carrier elements.

For this process, the construction material may be guided once through the process space or through the processing field, which is generated by a process source. The construction material is pulled through the processing field at an acute angle or at a very acute angle with respect to the determining flux direction, as a result of which the material used for coating is deposited in particular on areas of the line-shaped carrier elements, but also on areas of the node-shaped ones. This coating process is carried out to the extent that the free space area of the construction material is completely covered by the material producing the layer, without requiring a direct connection to a neighboring line-shaped carrier element.

In this way, the matrix- or lattice-shaped construction material, which was characterized by large areas of free space, is converted into a foil-like material. This converted material can now be further processed using conventional, state-of-the-art foil processing technology.

Such a covering of the free space areas of the matrix- or lattice-shaped construction material usually serves the purpose of building up on the top side and/or the bottom side of the winding material in a further step, i.e. in a second coating step technologically different from the first step, a layer consisting of one or more materials using vacuum technology, i.e. through vacuum coating processes. The covering layer helps to create an overall coating, comparable to the coating of a film. Furthermore, it allows the second coating step to also fill the empty space of the matrix- or lattice construction material with the material or materials deposited during this coating process.

These coating processes produce a construction material or a foil-like functional material that is surrounded by a compact, albeit usually porous coating, which means that its external solid appearance is practically no longer or only insignificantly different from a functional material in film form. For this reason, even if the name does not reflect the correct facts, this is often referred to as a functional foil, for example an electrode foil for using the material as an electrode.

The foregoing features and advantages of this invention will be better understood and appreciated after a careful study of the following detailed description of preferred non-limiting example embodiments of the invention herein, in conjunction with the accompanying drawings, which show in:

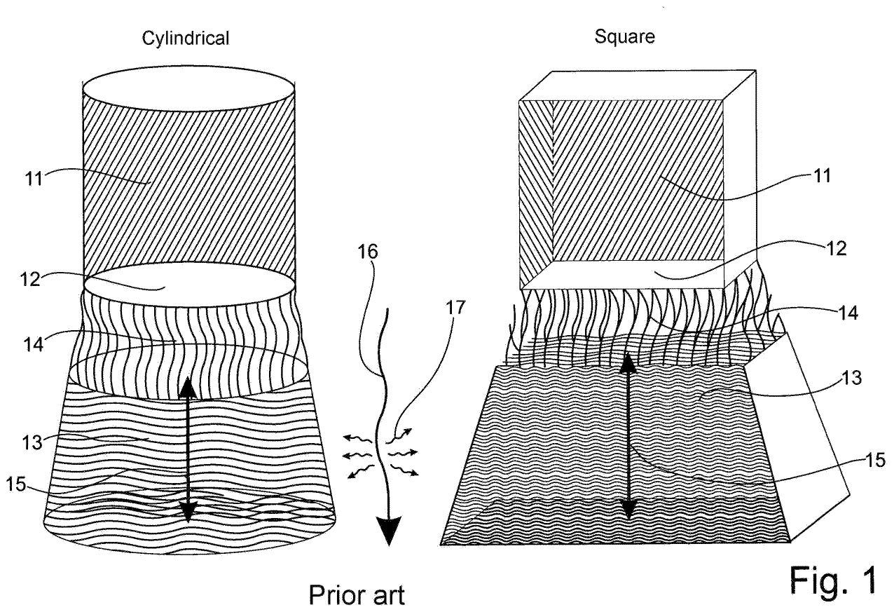

FIG. 1: a schematic diagram of two different process sources according to the prior art,

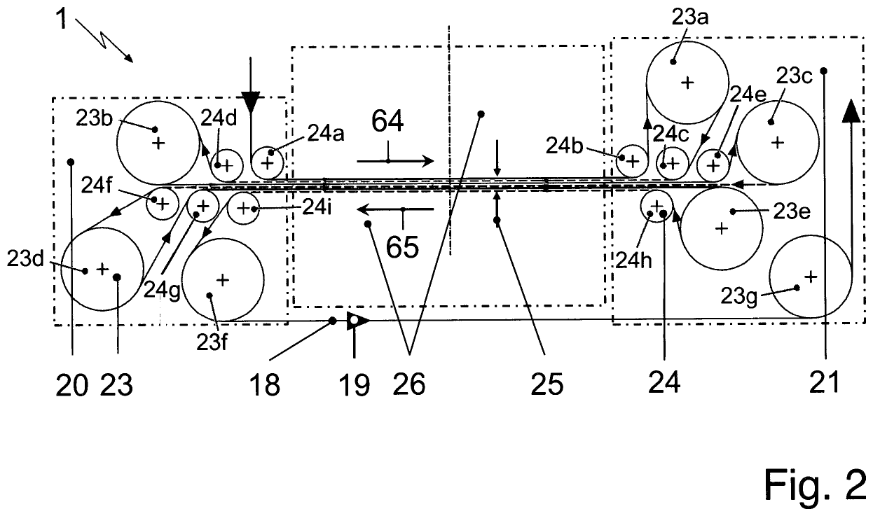

FIG. 2: an exemplary winding device according to the invention in a vacuum coating system for a matrix- or lattice-shaped construction material,

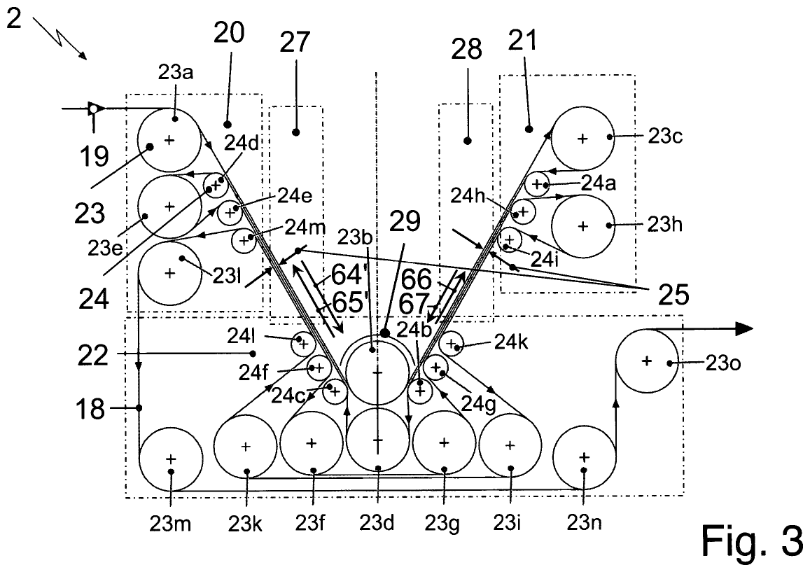

FIG. 3: another exemplary winding device according to the invention,

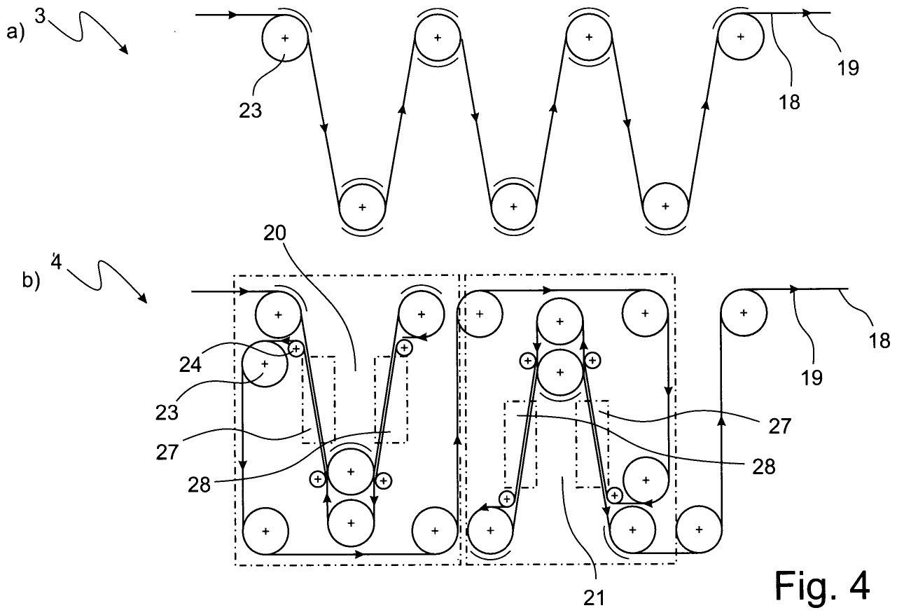

FIG. 4a: a winding system for a matrix- or lattice-shaped construction material,

FIG. 4b: another exemplary winding device according to the invention in a vacuum processing system in an embodiment with two areas or chambers,

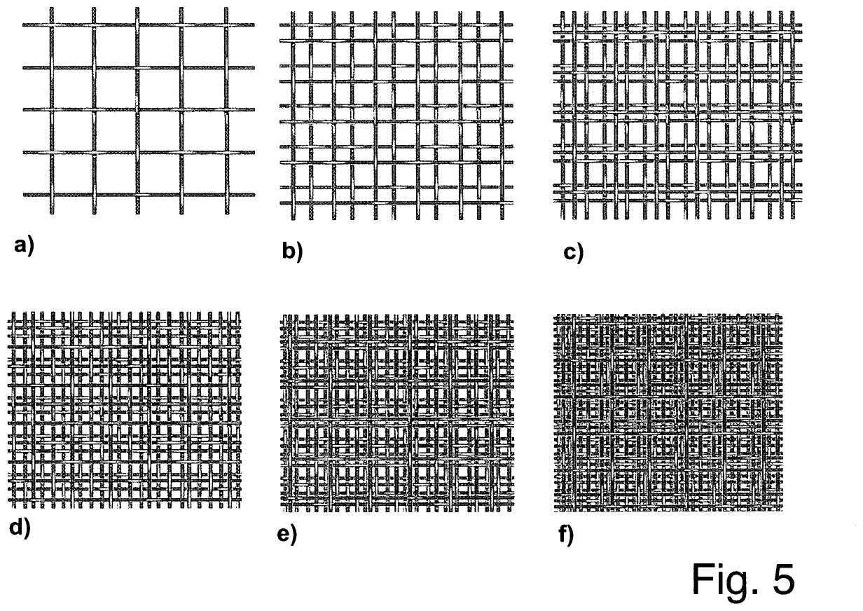

FIGS. 5a to 5f: a snapshot of the top view of a section of layers of the matrix- or lattice-shaped construction material moving over one another and against one another with an increasing number of layers,

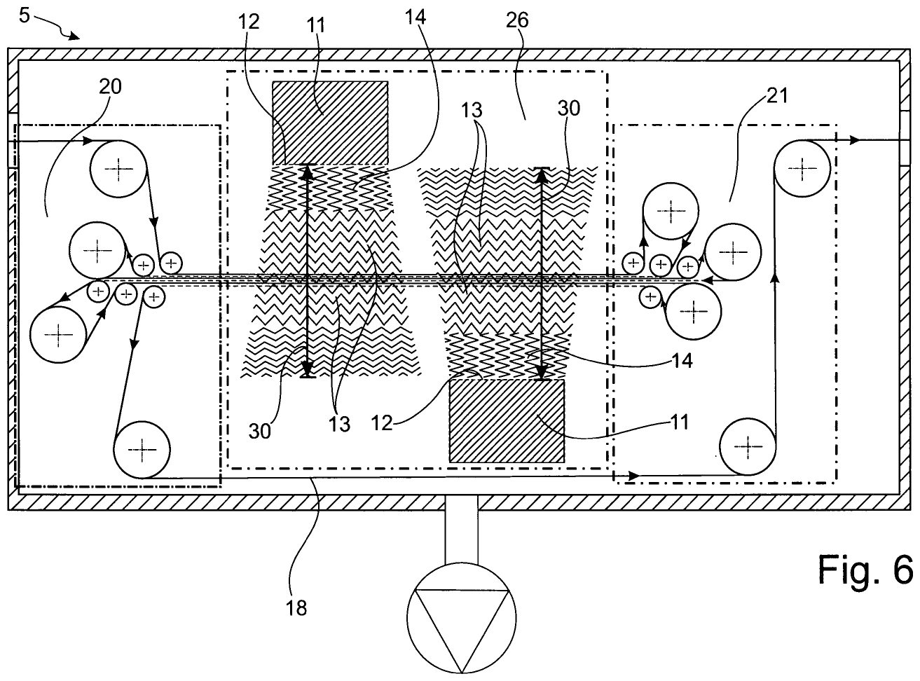

FIG. 6: a winding device designed according to the invention in a process chamber,

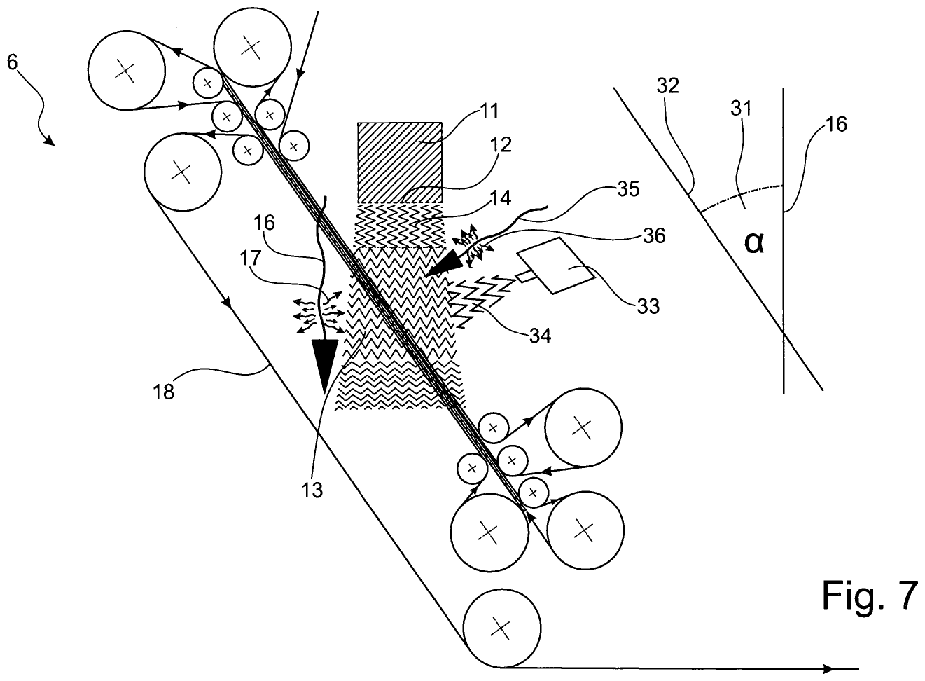

FIG. 7: another exemplary winding device,

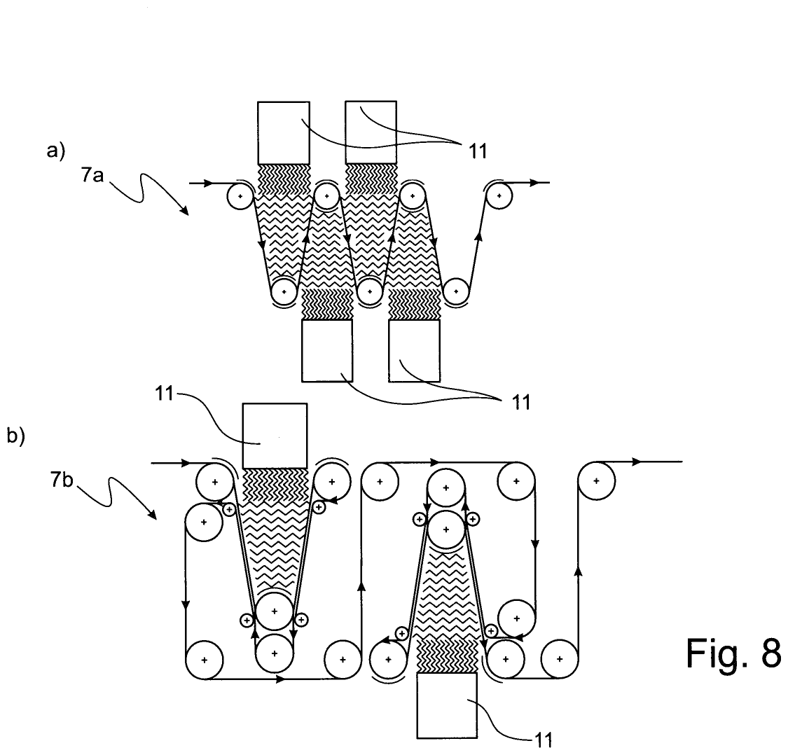

FIG. 8a: a schematic diagram of a processing, in particular of a coating,

FIG. 8b: a schematic diagram of a processing, in particular a coating, by using a winding system according to FIG. 4b,

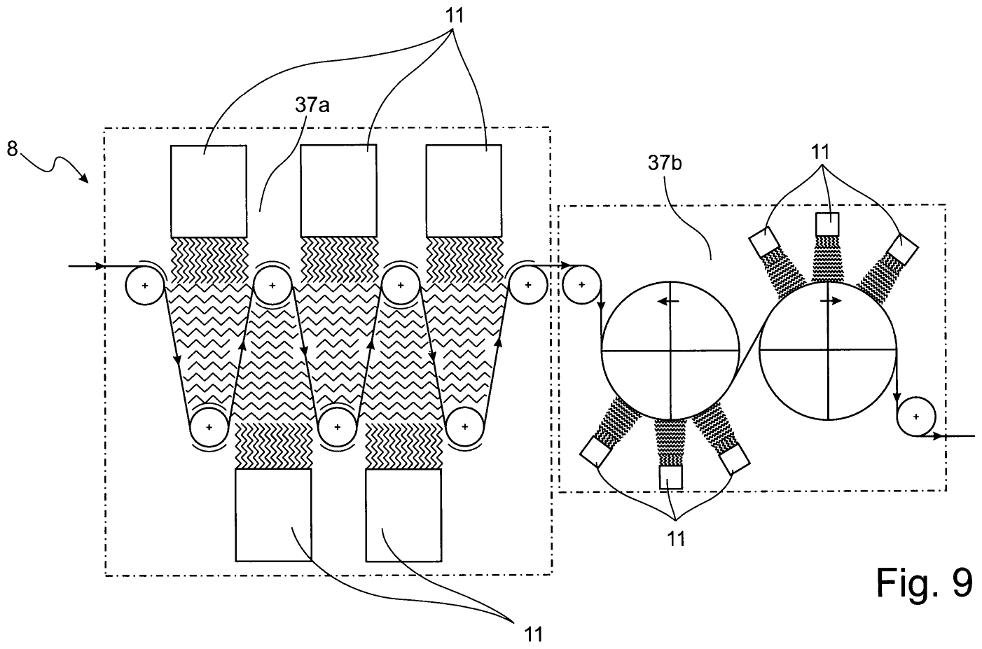

FIG. 9 a schematic diagram of a coating to explain a layer structure,

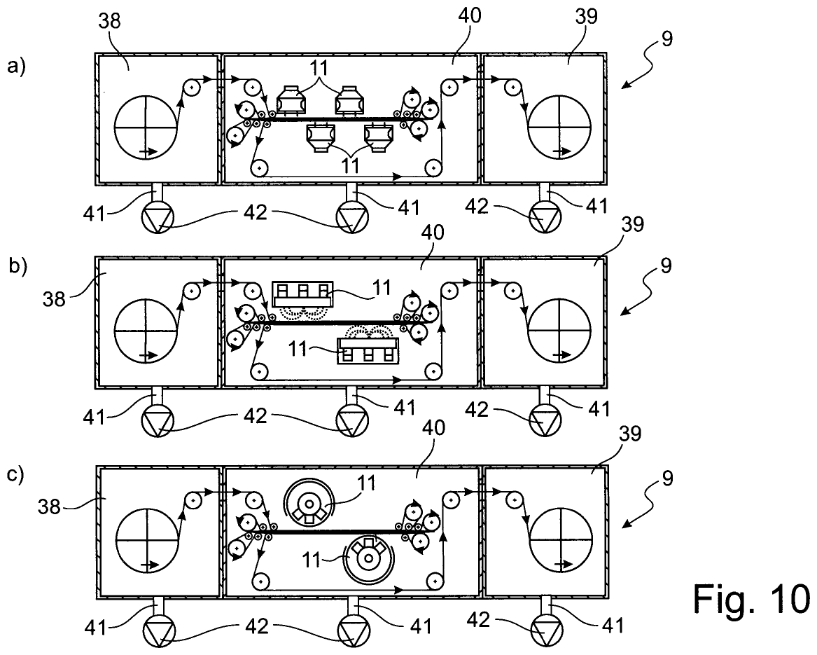

FIGS. 10a to c: exemplary vacuum processing systems with different process sources,

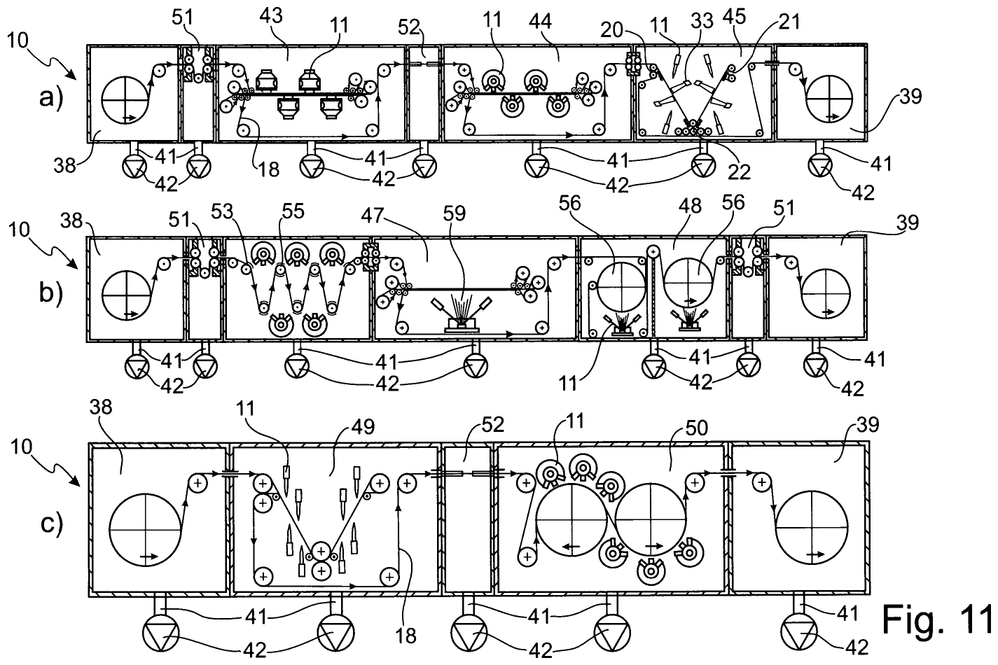

FIGS. 11a to c: exemplary configurations of vacuum processing systems with different process sources in different modules,

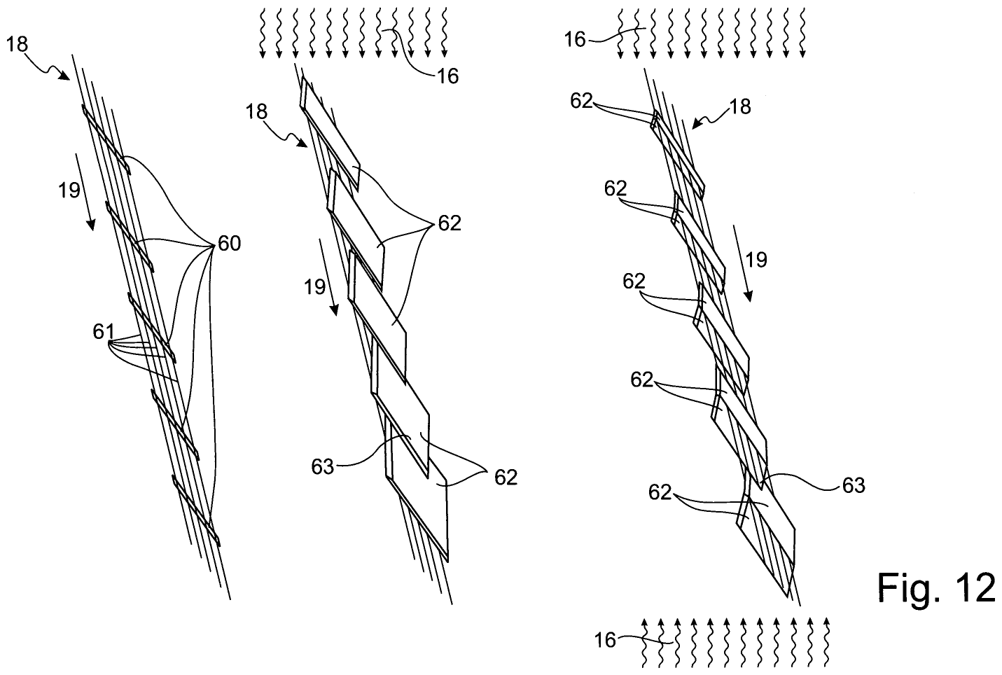

FIG. 12: a schematic diagram of a layered structure on the line-shaped carrier elements of the matrix or lattice-shaped construction material 18 in two variants, and

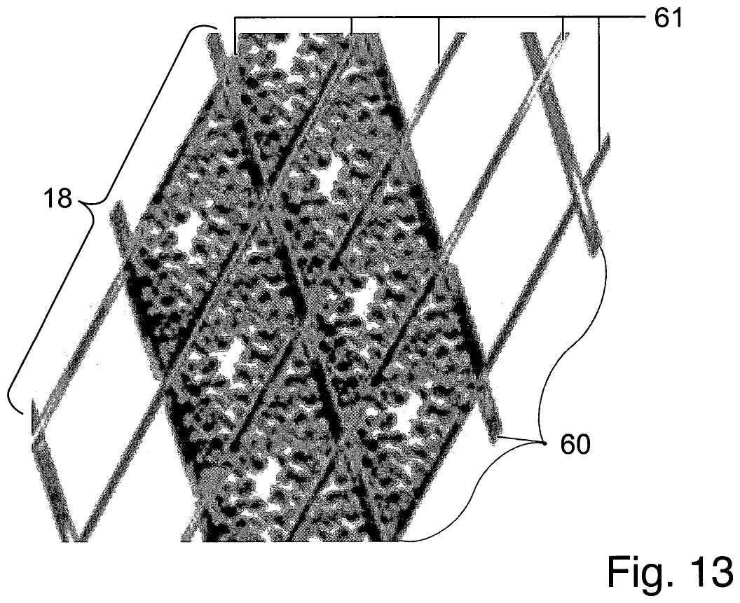

FIG. 13: a schematic diagram of filling of the voids of the matrix- or lattice-shaped construction material 18.

FIG. 1 shows a schematic representation of two different processing media 11 or process sources from the prior art, which is intended to help explain the terms processing instrument 11, field, current, flux, effect and effect intensity as well as the idioms usable flux 13, predetermined effective direction of the flux, principle flux propagating direction or to define the spread of the flux in more detail. FIG. 1 shows two different geometric forms of the processing instruments 11 or process sources used in vacuum technology in a schematic and generalized manner. One processing instrument 11 shown schematically and in a generalized manner has a cylindrical design and the other a cuboid design.

In principle, the processing instruments 11 can also have any other shape. The shape shown schematically and in a generalized manner in FIG. 1 reflects the most commonly used designs of such devices. However, it is not uncommon for other shapes to be used, for example composite shapes consisting of cuboid and cylindrical elements. The processing instrument 11 represents the field- or power-emitting unit, i.e. it is the source by which the flux is generated.

In most cases, the flux 13, whose field or current is generated in the processing instrument 11 or a process source 11, runs from a surface into the free space of the vacuum chamber. The spatial area in which the effect of the flux 13 can be felt and can be effective through interaction with the substrate to be coated is referred to as the usable extent of the flux. This area 12, from which the flux 13 propagates, is highlighted in FIG. 1 and is referred to as the effect-emitting area 12. Its existence is the result of the fact that a process source 11 does not represent a point size, but always a body with a three-dimensional, finite geometric extent, so that the effect is always emitted from a planar structure, i.e. a surface.

The effect caused by the flux represents a physical and/or chemical interaction process that acts on a solid, which is referred to as a substrate for the special application in vacuum technology, or in its near-surface area, causing an effect or a reaction. The effect is always associated with an energetic effect on the substrate, i.e. energy is transferred. This part of the effect is therefore referred to as energy input into the substrate.

The effect of the flux 13 can cause completely different physical and/or chemical effects or reactions on the surface or in the area close to the surface of the substrate. At this point, only a few of the multitude of possible effects and reactions should be listed in order to understand what is meant by effects and reactions.

An effect of a spreading flux 13 can, for example, involve the cleaning of a substrate surface. Activation processes can be brought about by individual effects on the substrate surface or in the region of the substrate close to the surface. Furthermore, with the help of special effects, physical and/or chemical etching can also be carried out in this substrate area. In addition, the properties of the flux 13 can in turn cause specially designed effects, such as oxidation processes or other chemical reactions, in the surface region or on the surface of the substrate. In addition, the substrate surfaces can be coated with one or more materials. In this case, the evaporant of the coating process provides the flux and the layer deposited on the solid portions of the substrate provides the special effect. According to the present invention, the matrix- or lattice-shaped construction material 18 represents the flexible substrate 18.

A usable flux 13 is to be understood as the particular spatial extent 13 of the flux which effects a substrate, i.e. physical and/or chemical effects or reactions with the substrate, i.e. on its surface or its near-surface area. For technical applications such as those used in vacuum systems, the spatial extent of the usable flux 13 is usually limited in such a way that the intensity at every point in space has almost the same magnitude or a magnitude in the same order of magnitude. This limitation can be specified using Equation (3) and is therefore an arbitrary definition, which, however, makes sense from a technical point of view. The length 15 of the extent of the limited field of action, which is defined perpendicularly to the flux exit surface 12, is referred to as the flux extent 15.

Quite frequently, a spatial area 14 of finite and therefore limited extent exists between the flux exit surface 12, through which the field or the flux of the processing medium 11 is emitted, and the usable flux 13, which is characterized in that although the desired effect is already taking effect and could also already be used, fields or currents are still effective whose forces, when interacting with a substrate, cause a feedback to the process source 11 or could cause a damaging and irreversible influence on the substrate. For this reason, the substrate must not be in this area while processing takes place. This spatial extent thus represents a forbidden spatial area 14 for the substrate and is therefore referred to as a forbidden zone 14.

The flux 13 propagates in a preferred direction 16, which is determined by the process source 11 and by the flux exit surface 12 and can be viewed as the primary direction 16 of the propagation of the flux 13, i.e. the propagation takes place in a fixed, predetermined direction determined by the source and by the flux exit surface 12. Basically, the flux 13 is effective during an interaction with the surface of the solid elements of a substrate or their near-surface areas from this preferred direction 16, i.e. the primary direction 16. Due to scattering processes, reflections and similar processes, the effect may experience an angular distribution 17 that can weaken, but not eliminate the intensity of the effect. Interactive processes therefore take place, the effects of which are subject to an angular distribution 17.

FIG. 2 shows an exemplary winding device 1 according to the invention in a vacuum processing system for a matrix- or lattice-shaped construction material 18 which moves through a winding device 1, a so-called “reel-to-reel” system 1. The flexible matrix- or lattice-shaped construction material 18 is moved in the winding direction 19 over two roller groups 20 and 21 or cylinder groups 20 and 21 consisting of several larger rollers 23 or larger cylinders 23 and several smaller rollers 24 or smaller cylinders 24. This embodiment using larger rollers 23 and smaller rollers 24 is an example and can be adapted accordingly by a person skilled in the art. For example, only smaller rollers 24 may be used to save space.

In a free region 26 in an evacuable process chamber or an evacuable process area in which no rollers or cylinders have to be arranged, which is located between the first roller group 20 and the second roller group 21, the flexible matrix- or lattice-shaped construction material 18 moves superpositioned with a small distance 25 from each other in mutually opposite directions. The magnitude of the length 25 marked by two opposing, oppositely directed arrows indicates the distance 25 between the uppermost and the lowermost layer of the matrix- or lattice-shaped construction material 18 transported in opposite directions.

At least one usable flux 13 of at least one processing instrument 11, which is arranged in one of the free regions 26, passes through the first and the second layer of the flexible substrate 18, i.e. the flexible matrix- or lattice-shaped construction material 18, during their opposite parallel transport through the free region 26 at the same time at a small distance 25 from one another, with the processing instrument 11 and the usable flux 13 not being shown in FIG. 2. In the event that more than two layers of the flexible substrate 18 are transported through the free region 26 at the same time, parallel and closely spaced from one another, the usable flux 13 of the processing instrument 11 will pass through more than two layers, i.e. through all layers of the flexible substrate 18.

Such a small distance between two adjacent layers of the matrix- or lattice-shaped construction material 18 transported in opposite directions may be in a range between approximately 1 mm and 10 mm, and this distance is in particular 2.5 mm.

The transport of the flexible matrix- or lattice-shaped construction material 18 over five smaller rollers 24 and three larger rollers 23 in the first roller group 20 and over four smaller rollers 24 and four larger rollers 23 in the second roller group 21 is shown in FIG. 2 by corresponding directional arrows shown on the matrix- or lattice-shaped construction material 18. As can be seen, for example, a first (upper) layer of the matrix- or lattice-shaped construction material 18 is transported from the roller 24a of the first roller group 20 to the roller 24b of the second roller group 21 in a first transport direction 64. In the second roller group 21, the construction material 18 in the form of a matrix or lattice is deflected via a small roller 24b, a large roller 23a and a small roller 24c in such a way that the matrix- or lattice-shaped construction material 18 is transported in a second layer of the matrix- or lattice-shaped construction material 18 in a second transport direction 65 from the roller 24c of the second roller group 21 to the roller 24d of the first roller group 20 at a close distance from the first layer of the matrix- or lattice-shaped construction material 18.

The matrix- or lattice-shaped construction material 18 is deflected in the first roller group 20 via a small roller 24d and a large roller 23b in such a way that the matrix- or lattice-shaped construction material 18 in a third layer of the matrix- or lattice-shaped construction material 18 is, while closely spaced from the second layer of the matrix- or lattice-shaped construction material 18, again transported in the first transport direction 64 from the large roller 23b of the first roller group 20 to a small roller 24e of the second roller group 21.

In the second roller group 21, the matrix- or lattice-shaped construction material 18 is deflected via a small roller 24e and a large roller 23c, so that the matrix- or lattice-shaped construction material 18 in a fourth layer of the matrix- or lattice-shaped construction material 18, while closely spaced from the third layer of the matrix- or lattice-shaped construction material 18, is again transported in the second transport direction 65 from the large roller 23c of the second roller group 21 to a small roller 24f of the first roller group 20.

In the first roller group 20, the construction material 18 in the form of a matrix- or lattice is deflected via the small roller 24f, a large roller 23d and a small roller 24g in such a way that the construction material 18 in the form of a matrix- or lattice is in a fifth layer of the construction material 18 in the form of a matrix- or lattice is transported again in the first transport direction 64 from the small roller 24g of the first roller group 20 to a large roller 23e of the second roller group 21 at a close distance from the fourth layer of the matrix- or lattice-shaped construction material 18.

In the second roller group 21, the matrix- or lattice-shaped construction material 18 is deflected via the large roller 23e and a small roller 24h in such a way that the matrix- or lattice-shaped construction material 18 in a sixth layer of the matrix- or lattice-shaped construction material 18 is closely spaced from the fifth layer of the matrix- or lattice-shaped construction material 18 is again transported in the second transport direction 65 from the small roller 24h of the second roller group 21 to a small roller 24i of the first roller group 20.

Subsequently, the matrix- or lattice-shaped construction material 18 is transported directly or by further rollers (not shown) in the direction of a take-up module 39 (not shown), which then takes up the matrix- or lattice-shaped construction material 18. In the example of FIG. 2, this is done in such a way that the matrix- or lattice-shaped construction material 18 is deflected via the small roller 24i and a large roller 23f and is transported to another large roller 23g without passing through the free region 26.

The unwind module 38, which is not shown in FIG. 2, is arranged, for example, in such a way that the matrix- or lattice-shaped construction material 18 is fed to the first small roller 24a directly or by other unillustrated rollers.

This process of deflecting the matrix- or lattice-shaped construction material 18 and transporting it between the first group of rollers 20 and the second group of rollers 21 or vice versa is carried out six times in FIG. 2, for example, so that the matrix- or lattice-shaped construction material 18 is moved closely spaced from one another in six layers through the free region 26 in a process chamber or a process area. From the perspective of a processing instrument 11 or a process source 11, not shown in FIG. 2, in the direction of the six-layer guide of the matrix- or lattice-shaped construction material 18, the result is a view that corresponds to the representation in FIG. 5f. Compared to a single layer coating where the process source “sees” the matrix- or lattice-shaped construction material 18 as shown in FIG. 5a, there is a substantial reduction in the voids of the matrix- or lattice-shaped construction material 18 from the “view” of the process source 11. It should be noted that the diagrams in FIG. 5 each correspond to a snapshot and therefore cannot fully illustrate the dynamics of the actually occurring process.

As a result, more material to be coated or material that is used for surface-finishing the matrix- or lattice-shaped construction material 18 encounters the six-layer matrix- or lattice-shaped construction material 18, and the processing or coating is much more effective than would be possible with just one layer of the matrix- or lattice-shaped construction material 18.

A limitation to this number of six layers is not intended. A corresponding adjustment of the number of layers and the first roller group 20 and the second roller group 21 can be made by a person skilled in the art.

Likewise, the winding device 1 does not necessarily have to be arranged horizontally, but may as well be arranged vertically or at an oblique angle. In this case, one would then no longer refer to superpositioned layers, but to layers of the matrix- or lattice-shaped construction material 18 lying next to one another.

Although not shown here, suitable processing instruments 11 or process sources 11 may be arranged in the free region 26 of the process chamber that is used to, for example, apply material suitable for coating to the matrix- or lattice-shaped construction material 18. Such processing instruments 11 can be arranged in the free region 26 both on a first side of the closely spaced layers of the matrix- or lattice-shaped construction material 18, which preferably run parallel to one another and in opposite directions, for example above, and on a second side, for example below, of the matrix- or lattice-shaped construction material 18. The number of processing instruments 11 to be arranged in the free region 26 may also vary.

The winding system 1 according to the invention is suitable for surface treatment processes, such as ion treatment with energetic ions or for coating processes that cause an enveloping coating of the line-shaped and node-shaped carrier elements of the matrix- or lattice-shaped construction material 18, and possibly with some limitations for coating processes that are used to fill the voids of the matrix- or lattice-shaped construction material 18.

FIG. 3 shows schematically a further exemplary “reel-to-reel” system 2 which satisfies the subject matter of the invention. This winding device 2 consists of three roller groups 20, 21 and 22. The winding system 2 includes two free regions in a process chamber, namely the first free region 27 and the second free region 28, through which the matrix- or lattice-shaped construction material 18 is transported back and forth several times. The shielding plate 29, which is shown here only as an example, serves to shield any effect from a flux Φ, which is caused by the field or by the current that is generated in a processing instrument 11, in order to protect the rollers or rollers arranged behind the matrix- or lattice-shaped construction material 18, which would be exposed to a direct effect, against this effect.

The matrix- or lattice-shaped construction material 18 is transported back and forth several times both in the free regions 26 of FIG. 2 and in the first free region 27 and in the second free region 28 of FIG. 3. The matrix- or lattice-shaped construction material 18 moves at a small distance 25 from one another, arranged one above the other, in opposite directions. The matrix- or lattice-shaped construction material 18 is thus transported in FIG. 3 through the first free region 27 in a first direction, such as a first transport direction 64′, and in a second transport direction 65′, which is opposite to the first transport direction 64′. In addition, the matrix- or lattice-shaped construction material 18 in FIG. 3 is transported through the second free region 28 in a third direction, such as a third transport direction 66, and in a fourth transport direction 67, which is opposite to the third transport direction 66. As shown in FIG. 3 by way of example, this process can be continued with further layers of the matrix- or lattice-shaped construction material 18. An angle is provided between the first and the third transport direction (64′, 66) and the second and the fourth transport direction (65′, 67), which can be in a range between greater than 0 degrees and less than 180 degrees. The angle is in particular in a range between 30 degrees and 150 degrees. In the example of FIG. 3, an angle of about 60 degrees is selected.

In the example of FIG. 3, the matrix- or lattice-shaped construction material 18 is first moved from the large roller 23a of the first roller group 20 through the first free region 27 to a large roller 23b of the third roller group 22 in a first transport direction 64′. The matrix- or lattice-shaped construction material 18 is then deflected over the large roller 23b and transported from the third roller group 22 through the free region 28 to another large roller 23c of the second roller group 21 in a third transport direction 66.

The flexible matrix- or lattice-shaped construction material 18 is deflected over the large roller 23c and a small roller 24a and transported a second time in a fourth transport direction 67 from the small roller 24a of the second roller group 21 through the second free region 28 via the small roller 24b to a large roller 23d in the third roller group 22.

In the third roller group 22, the matrix- or lattice-shaped construction material 18 is deflected over the large roller 23d and the small roller 24c and transported a second time from the third roller group 22 to a small roller 24d in the first roller group 20 through the free region 27 in a second transport direction 65′.

In the first roller group 21, the matrix- or grid-shaped construction material 18 is then deflected over the small roller 24d, a large roller 23e and the small roller 24e and again transported a third time in the first transport direction 64′ from the first roller group 20 to a small roller 24f in the third roller group 22 through the free region 27.

In the third roller group 22, the matrix- or lattice-shaped construction material 18 is subsequently deflected over the small roller 24f, a large roller 23f and another large roller 23g and a small roller 24g and again transported in the third transport direction 66a third time from the third roller group 22 to a small roller 24h in the second roller group 21 through the free region 28.

In the second roller group 21, the matrix- or lattice-shaped construction material 18 is subsequently deflected over the small roller 24h, a large roller 23h and a small roller 24i and again transported a fourth time from the second roller group 21 to a small roller 24k in the third roller group 22 through the free region 28 in the fourth transport direction 67.

In the third roller group 22, the matrix- or lattice-shaped construction material 18 is subsequently deflected via the small roller 24k, a large roller 23i and a large roller 23k and a small roller 24l and again transported a fourth time from the third roller group 22 to a small roller 24m in the first roller group 20 through the free region 27 in the second transport direction 65′.

After reaching the small roller 24m, for example, the intended processing processes, such as coating processes, are completed and the matrix- or lattice-shaped construction material 18 is transported to a take-up module 39. In the example of FIG. 3, this transport takes place via the large rollers 23l, 23m, 23n and 23o.

A limitation to this number of four layers is not intended. A person skilled in the art can adjust the number of layers accordingly.

The unwind module 38, also not shown in FIG. 3, is arranged, for example, in such a way that the matrix- or lattice-shaped construction material 18 is fed to the first large roller 23a directly or by way of unillustrated other rollers.

The winding system 2 is also suitable for surface treatment processes, such as ion treatment with energetic ions, but especially for coating processes intended to fill up the voids in the matrix- or lattice-shaped construction material 18. If necessary, it can be used for coating processes to produce an enveloping coating of the line-shaped and node-shaped carrier elements of the matrix- or lattice-shaped construction material 18.

FIG. 4 shows schematically two further winding systems, namely a “reel-to-reel” system 3 in FIG. 4a and a “reel-to-reel” system 4 in FIG. 4b. FIG. 4a shows a winding system 3 designed to move the flexible matrix- or lattice-shaped construction material 18 through the roller system in a single layer. The rollers 23 are arranged in such a way that the matrix- or lattice-shaped construction material 18 is transported between every three rollers at an acute angle. Three respective rollers 23, two adjacent upper ones and the lower one in between, or two adjacent lower ones and the upper one in between, are arranged accordingly. In many applications, the angle is 0°.

FIG. 4b shows schematically a “reel-to-reel” system 4, which consists of two groups of rollers 20, 21. In principle, the winding system 4 enables four free regions, two free regions 27 and two free regions 28, through which the flexible substrate 18 or the matrix- or lattice-shaped construction material 18 is transported back and forth once. The matrix- or lattice-shaped construction material 18 thus moves in two layers in opposite directions through the free regions 27 and 28. The angle spanned between the layers of the matrix- or lattice-shaped construction material 18 is again extremely acute. In many applications, this angle is ≤10°.

The winding systems 3 and 4 in FIGS. 4a and 4b are suitable for surface treatment processes, such as ion treatment with energetic ions, but especially for coating processes that cover the voids of the matrix- or lattice-shaped construction material 18. The extremely acute angle spanned between three rollers 23 in FIG. 4a or between the layers in FIG. 4b causes a relatively thin layer to build form during a coating process on sections, for example on an edge, of the line-shaped and node-shaped carrier elements of the matrix- or lattice-shaped construction material 18, with the primary direction 16 of the particles of the coating material emitted by a processing instrument 11 representing one leg of the acute angle and the moving matrix- or lattice-shaped construction material 18 representing the other leg.

If a processing instrument 11, which emits its propagating field or current as a flux Φ at a predetermined angle in the direction of the matrix- or lattice-shaped construction material 18, is located above the top layer or below the bottom layer of the matrix- or lattice-shaped construction material 18, an interaction occurs with the surfaces or the near-surface area of the solid elements of the matrix- or lattice-shaped construction material 18. Due to the small surface area of a layer of the matrix- or lattice-shaped construction material 18, the proportion of the solid elements in the total area occupied by the layer is small. Due to the fact that several layers of the matrix- or lattice-shaped construction material 18 move against one another at a small distance, the proportion of solids in the winding material that is usefully exposed to the effect of the flux Φ increases significantly.

FIG. 5 shows schematically the increase in the proportion of solids due to the overlapping of the individual layers of the matrix- or lattice-shaped construction material 18. FIG. 5a shows schematically the section of a layer of a fabric, which illustrates in the figure a large-meshed plain weave and corresponds to the matrix- or lattice-shaped construction material 18. FIG. 5b illustrates the snapshot when two such layers, FIG. 5c when three layers, FIG. 5d when four layers, FIG. 5e when five layers and FIG. 5f when six layers are arranged on top of one another. As can be clearly seen, the more layers there are on top of one another, the more the field of view is filled with solid surface portions of the carrier elements when looking at the upper or lower side of the matrix- or lattice-shaped construction material 18. On this basis, the surface treatment processes that take place on the solid components of the winding material can be used because due to the layer formation of the matrix- or lattice-shaped construction material 18, substantially more solid material than would be required for transporting a single layer of matrix- or lattice construction material 18 through this area is located in the spatial area of the usable flux Φ_{usable} produced by the treatment instrument 11 where the desired effect is generated.

In FIG. 6 shows schematically and in generalized form the effect of the arrangement 5, the core of which is the winding system 1 from FIG. 2, on a matrix- or lattice-shaped construction material 18, which moves through the winding system 1. In most cases, the effect of processing the solid components, i.e. their surfaces or their near-surface areas, are considered to be equal. The effect on the matrix- or lattice-shaped construction material 18 in FIG. 6 is triggered by two respective processing instruments 11 which serve as source for the propagation of the flux 30 in a free region 26 located between the roller systems 20 and 21. The respective expanding field or the respective current that is emitted, i.e. the flux Φ, impinges on the matrix- or lattice-shaped construction material 18 and acts on its surface or the near-surface area of its solid components. One of the two processing instruments 11 is arranged above the uppermost layer of the matrix- or lattice-shaped construction material 18 in the free region 26 and the second is arranged below the lowermost layer of the matrix- or lattice-shaped construction material 18. The expansion of the flux 30 runs from the flux exit surface 12 of the processing instrument 11 in the direction of the matrix- or lattice-shaped construction material 18. The forbidden zone 14 and the area of the usable flux 13 are penetrated by the flux 30. Since the extent of the area traversed by the flux 30 is characterized by its primary direction 16 (see FIG. 1), the effect occurs on those solid components of the layers of the matrix- or lattice-shaped construction material 18 that can be freely hit by the flux.

Furthermore, an angular distribution of the effect is likely to occur in the vicinity of the surface of the matrix- or lattice-shaped construction material 18. This increases the effect by which the surface or near-surface area is influenced.

The use of two processing instruments 11, which are shown schematically and in abstract form in the illustration in FIG. 1, from two fundamentally qualitatively different directions, is intended to illustrate that it is technically and practically possible to realize the effect on the matrix- or lattice-shaped construction material 18, for example by way of processing, from two in principle qualitatively different directions, namely both above and below the transported matrix- or lattice-shaped construction material 18. The terms upper and lower sides mean that in principle there are two opposite sides in which the matrix- or lattice-shaped construction material 18 expands in a two dimensions. The processing instruments 11, which are used as the source of the flux that produces an effect, can be arranged in the two spaces or free regions 26 spanned in the opposite direction of the layer package formed by the meandering movement of the matrix- or lattice-shaped construction material 18. Different angles for the primary direction 16 of the propagation of the flux causing an effect can be set on both sides, i.e. both from the top and from the bottom, see FIG. 1. The flux also impinges on the solid portions of the layers disposed between the top and bottom layers. The design of the employed processing tools 11, i.e. the primary direction 16 and the angle at which the processing tools 11 emit their fields and/or currents and their number, depends on quite a few different conditions and parameters. These are, among other things, design conditions, requirements of the special processing processes, the processing intensity, the prevention of mutual influence of neighboring processing media and several other conditions and parameters.

The arrangement 5 shown in FIG. 6 can be used for surface treatment processes, such as cleaning, etching, chemical reaction processes, for example oxidation, nitration or polymerization, of the matrix- or lattice-shaped construction material 18 constituting the winding material.

If an enveloping coating of the solid components of the matrix- or lattice-shaped construction material 18, i.e. of the line-shaped and node-shaped carrier elements, is to be performed with a material to be coated, it is advisable to also use the arrangement 5 with the winding system 1 shown in FIG. 6.

Such processing media 11 or processing instruments 11 are devices for cathode sputtering, such as planar magnetrons, tube magnetrons or sputter ion sources, or thermal evaporator units, such as resistance evaporators, electron beam evaporators, arc evaporators or an arc evaporation device, laser evaporators and several others. In order to ensure an enveloping coating of the line-shaped and node-shaped carrier elements, an appropriate working pressure must be selected, which is generally in the range between 1×10⁻³ mbar and 5×10⁻² mbar.

It should be noted that processing instruments 11 exist that can only emit their field or current upwards from below. Others, in turn, offer the technical possibility of being able to send the field in all spatial directions. These device-specific conditions must be taken into account when arranging the units.

The core element of the arrangement 6, which is shown in FIG. 7, is in turn the winding device 1 from FIG. 2. Two important aspects of affecting the matrix- or lattice-shaped construction material 18 will be described with reference to FIG. 7.

On the one hand, the intent is to show in a schematic and abstract manner that the matrix- or lattice-shaped construction material 18 can be influenced at very specific, fixed angles 31, for example the angle α. When determining the angle α, i.e. the angle 31, which is subtended between the preferred direction 16 of the flux, i.e. the primary direction 16, and the magnitude of the direction of movement 32 of the layer stack of the matrix- or lattice-shaped construction material 18, it is important to note that the matrix- or lattice-shaped construction material 18 moves within the range of useful flux 13. Care must therefore be taken to absolutely ensure that the matrix- or lattice-shaped construction material 18 does not come into contact with the area of the forbidden zone 14.

On the other hand, the intent is to show in a schematic and abstract manner that the case or the technical requirement may arise in a wide variety of applications that the effect originally caused by the processing instrument 11 can be influenced by a second effect, which should therefore be referred to as a secondary effect, and is to be understood as an influencing effect. A second processing instrument 33, which is to be referred to as an influencing effect instrument, is used as the influencing source for the secondary effect. This source sends out a second field or a second current, the flux 34 of which, i.e. a second flux 34, also produces an effect. As a rule, this second flux 34 likewise emerges from a flux exit surface of the instrument 33 for influencing the effect. The special feature of this emitted special flux 34 is that it interacts with the flux 13, whose influencing source is the processing instrument 11 and which is emitted through its flux exit surface 12, without producing the effect nor evoking the reaction on the surface or in the near-surface area of the solid components of the matrix- or lattice-shaped construction material 18, meaning the intended effect, i.e. the processing. In other words, the secondary effect provides no immediate or direct contribution that affects the matrix- or lattice-shaped construction material 18. The secondary effect causes, based on the interaction with the flux emitted from the processing instrument 11, only influences this effect on the surface or the near-surface area of the solid components of the matrix- or lattice-shaped construction material 18. The interaction can cause the intensity of the effect to increase, remain the same, or decrease. It depends on the parameters of the influencing instrument 33 and the associated flux 34. The interaction between the two fluxes 13 and 34, however, always causes the effect influencing the surface or the area close to the surface of the solid components of the matrix- or lattice-shaped construction material 18 to have another additional orientation. In general, the preferred direction 16 with its angular distribution 17 produces a new angular distribution depending on the second flux 34 with its angular distribution 36. In an extreme case, the secondary direction 35 in the new angular distribution can dominate or even completely obscure the primary direction 16. In this way, the effect can be brought to a certain extent into the interior of the layer stack, i.e. into the free regions of the meandering layers of the matrix- or lattice-shaped construction material 18 that move towards one another, and affect the solid components located in the layers, enabling a correspondingly effective processing of the matrix- or lattice-shaped construction material 18.

If the flux is a stream of particles and the effect is a build-up of layers, then a coating process results. The components of the coating, i.e. the particles that are to be deposited, even if they can penetrate into the free spaces of the meandering moving layers of the winding material, can only be deposited at those points where this is possible. The separated particles can only be deposited on or adhere to solid components. In the specific case, these are the line-shaped or node-shaped carrier elements of the matrix- or lattice-shaped construction material 18, which can also already have an enveloping coating. This means that only this portion of the particles produced for the coating contributes to the coating effect. All other particles are practically lost. For this reason, a relatively acute angle α between layer movement and the primary direction of propagation of the effect-generating flux 13 is proposed in order to have as much area as possible of the line-shaped elements available for deposition. Furthermore, on the one hand, the superposition of the individual layers essentially builds up a wall of solid components which extremely restricts the penetration of the coating particles through the entire meandering layers moving against one another and, on the other hand, enormously reduces the proportion lost for the coating process. It can thereby be ensured that a significantly large proportion of the separated particles are deposited in the voids of the matrix- or lattice-shaped construction material 18.

In FIG. 7, the processing instruments 11 are arranged above the layers of the matrix- or lattice-shaped construction material 18 that move in a meandering manner relative to one another. However, they could also be arranged underneath.

If, in particular, the line-shaped carrier elements with or without an enveloping coating, but also the remaining carrier elements with or without an enveloping coating, are to be coated with one or more materials in such a way that the free space areas of the matrix- or lattice-shaped construction material 18 are covered, without having to strive for a covering filling the entire volume with the substances used for coating, then arrangements 7 can be used that are shown schematically and in abstract form in FIG. 8, specifically arrangements 7a shown in FIG. 8a and arrangements 7b shown in FIG. 8b. It is important to note that these figures are merely illustrative, i.e. they only show the principle of the coating. The type and number of coating units used and their particular arrangement ultimately depends on the respective conditions. Such conditions are, for example, the size of the available space for the installation of the units, the prevention of mutual interference, the material properties of the matrix- or lattice-shaped construction material 18 to be coated and others.

The carrier elements or the envelopingly coated carrier elements, in particular the line-shaped carrier elements, are coated using the principles outlined in FIG. 8. If the coating process is carried out with sufficient intensity, a thin layer is formed, which can extend as far as the next carrier element, without requiring contact with or adherence to the carrier element. However, this expansion of the layer causes an area-wide effect, that is, the free spaces spanned between the carrier elements or between the envelopingly coated carrier elements are covered by this layer without filling the entire volume. However, a covering envelope is formed. In this case, a constellation can certainly occur where several covering layers are formed, which in their entirety cover the free space and thus lead to a completely covering envelope of the free space area.

Such a method is always used when a layer structure is to be produced above and/or below the matrix- or lattice-shaped construction material 18. This can then be implemented subsequently using a conventional coating process.

FIG. 9 shows schematically and in abstract form an arrangement 8, which shows the method of building up layers of a matrix- or lattice-shaped construction material 18 in form of a diagram. The arrangement 8 is divided into two parts. As the arrangement 7a in FIG. 8 demonstrates, the first partial arrangement 37a serves to close the voids of the matrix- or lattice-shaped construction material 18, which is used as the flexible substrate 18, with the material to be coated in the form of a covering. The second partial arrangement 37b corresponds to a conventional coating structure with processing instruments 11, so that the top and/or underside can be coated with one or more substances in a vacuum based on the technology used with conventional film processing.

In FIG. 10, the arrangement 1 that is shown schematically in FIG. 2 is integrated in a simple embodiment of a “reel-to-reel” vacuum processing system 9. The vacuum processing system 9 has a modular structure and consists of an unwind module 38, a processing module 40 and a take-up module 39. Each module has a pump nozzle 41, which allows the individual chambers or modules to be evacuated with a pumping system 42, which can consist of various combinations of the components valves, high-vacuum and backing pumps. The neighboring modules are each connected via a common opening, which must be sealed to the outside, i.e. to atmospheric pressure. As a result, there are no locks integrated between the individual modules, so that the chamber system can also be evacuated using just one pump system, consisting of a vacuum pump pipe feed, valve, backing vacuum pump and high vacuum pump.

In FIG. 10a, four processing instruments 11 are installed in the processing module 40 of the vacuum processing system 9 as an example. In the case of FIG. 10a, these units are ion sources 11, which emit linearly accelerated energetic ions for processing the surfaces of the solid components of the matrix- or lattice-shaped construction material 18 moving in a meandering manner.

In FIGS. 10b and 10c, two processing instruments 11 are used in the processing modules 40 of the vacuum processing system 9 as an example. In this case, these units are cathode sputtering devices 11, i.e. in FIG. 10b embodied as a planar magnetron 11 and in FIG. 10c embodied as a tubular magnetron 11, which are used to perform a coating process above and below the matrix- or lattice-shaped construction material 18 moving in a meandering manner. This arrangement is used to achieve an enveloping coating of the line-shaped and node-shaped carrier elements of the matrix- or lattice-shaped construction material 18. Other necessary conditions for this process, which causes an enveloping coating, such as the parameters of the working pressure, are to be set commensurate with the process requirements.

Substantially comparable pressure conditions exist in all three modules, i.e. in the unwind module 38, in the processing module 40 and in the take-up module 39, although each chamber can be pumped out separately. The pressure range is determined by the requirements of the processing instruments 11. FIG. 10 is intended to reflect the variability of the processing options that are possible with the winding devices according to the invention, in this case the arrangement 1 from FIG. 2, for matrix- or lattice-shaped construction materials 18.

FIG. 11 shows various system configurations 10a, 10b and 10c, all of which represent “reel-to-reel” vacuum processing systems, giving various examples to illustrate the principle of effective processing of matrix- or lattice-shaped construction materials 18. All systems have an unwind module 38 and a take-up module 39. All modules can be evacuated separately, since each module has a pump connection 41, to which a pumping system 42 adapted in each case to the special function is connected.

FIG. 11a shows schematically and in abstract from a “reel-to-reel” vacuum processing system 10a for the internal filling of the voids of a matrix- or lattice-shaped construction material 18 with a coating material.

The first processing step takes place in module 43. This step embodies ion processing. By employing ion sources 11, the surface of the solid components of the matrix- or lattice-shaped construction material 18 is processed with energetic ions. At the same time, an activation process can take place. In order to be able to transfer the ion sources 11 to their operating range, a working pressure in the range between 1·10⁻⁰⁴ mbar and 8·10⁻⁰⁴ mbar must settable in this module. In the unwind module 38, however, only a pressure value in the range of 10⁻⁰¹ mbar or even higher is generally required, i.e. the pressure difference between the unwind module 38 and module 43 is extremely large. For this reason it is advisable to install a lock chamber 51 between the two modules, which can be pumped out separately. The lock chamber 51 contains roller locks providing an extraordinarily high level of leak-tightness. As a result, a disruptive gas exchange from the unwind module 38 to the module 43 can be largely prevented, even in the case of large pressure differences.

The winding device for the transport of the matrix- or lattice-shaped construction material 18 in the module 43 corresponds to the winding device 1, which is shown diagrammatically in FIG. 2. This device enables the matrix- or lattice-shaped construction material 18 to be moved in a meandering manner past the exemplary four ion sources 11, i.e. two above and two below the stack of layers.

In order to avoid gas exchange between module 44 and module 43 as far as possible, a lock chamber 52, this time by way of example a slit lock, has been installed between these two chambers. The difference in the working pressure ranges between the two modules is less than that between module 43 and unwind module 38. For this reason, the use of a slit lock 52, as shown in FIG. 11a between modules 43 and 44, is sufficient for many applications. A winding device 1, which is shown schematically in FIG. 2, is also installed in the module 44. Using the four tube magnetrons 11, with two magnetrons 11 being arranged above and two magnetrons 11 being arranged below the stack of layers in which the matrix- or lattice-shaped construction material 18 is transported in a meandering manner, an enveloping coating of the line-shaped and node-shaped carrier elements of the matrix- or lattice-shaped construction material 18 is generated. Since the magnetrons can work in the range from 1·10⁻⁰³ mbar to about 5·10⁻⁰¹ mbar, it can be readily understood why the pressure difference between module 44 and module 43 is lower than between unwind module 38 and module 43.

In the module 45, vacuum arc spraying devices 11 are installed as processing instruments 11. The voids spanned by the line-shaped and node-shaped carrier elements of the matrix- or lattice-shaped construction material 18 that have been envelopingly coated in the module 44, can be filled with a material using these units. For this purpose, the matrix- or lattice-shaped construction material 18 is transported via the winding device 2 from FIG. 3. In this winding device 2, which consists of three groups of rollers 20, 21 and 22, two layer stacks are formed, where the matrix- or lattice-shaped construction material 18 moves in a meandering manner past the processing media. A vacuum arc spraying device 11 used to perform the coating process for filling the voids is arranged on each layer side. A second processing medium 33, which in the present application is a gas nozzle 33, is used in addition to the primary direction, i.e. the preferred direction of the particle flux generated by the vacuum arc spraying devices 11, to generate another preferred direction, referred to as the secondary direction, for a portion of the generated particle flux. Due to other interaction processes occurring in the vicinity of the surface of the matrix- or lattice-shaped construction material 18, the generated particles experience additional angular distributions. On the basis of these interaction processes occurring during the coating process, the voids are filled with the coating material sprayed from the vacuum arc spraying devices 11.

The working pressure for vacuum arc spraying is between 10⁺⁰² mbar and 10⁺⁰³ mbar, which means that the difference between the working pressure in module 44 and module 45, in which the coating units are operated, is also extremely large. For this reason, a roller lock, through which the winding material is transported, is installed between the module 44 and the module 45. In many applications, a lock chamber 51 with roller locks is even required, which then has to be installed between these two modules.

Since there are generally no special requirements for the take-up module 39, its pressure range can be adapted to that in the module 45. For this reason, the installation of a slit lock 58 between these two modules is entirely sufficient.

FIG. 11b shows schematically a “reel-to-reel” vacuum processing system 10 for coating the top and bottom of a matrix- or lattice-shaped construction material 18. In module 46, the winding device 7a, shown schematically in FIG. 8, in particular the line-shaped carrier elements with or without an enveloping coating, but also the remaining carrier elements are coated with one or more materials, so that the voids of the matrix- or lattice-shaped construction material 18 are covered, without having to fill the entire volume with the substances used for the coating. If the coating process is carried out sufficiently intensively, a layer is formed that can extend to the next carrier element. This expansion of the layer represents an area-covering object. This means that the free spaces that open up between the carrier elements or between the carrier elements covered with an enveloping coating are covered with this built-up layer. Since this coating process often requires a large quantity of coating material, it makes sense to arrange several modules of the type module 46 sequentially before, for example, the module 47 is integrated.

To produce a covering envelope for the matrix- or lattice-shaped construction material 18, tube magnetrons 11 are used in module 46 in FIG. 11b, which deposit or release or sputter the material to be deposited with a respective acute angle spanned, for example, by the moving matrix- or lattice-shaped construction material 18 and three deflection rollers, such as the upper left deflection roller 53, the lower left deflection roller 54 and the adjacent upper deflection roller 55 on the right side. FIG. 11b shows schematically five exemplary tubular magnetrons. The magnetrons are arranged in such a way that the particles of the material to be sputtered preferably move substantially in the plane spanned by the matrix- or lattice-shaped construction material 18. The acute angle, which is preferably ≤10°, ensures that in particular the line-shaped carrier elements are coated in such a way that a layer is built up on the solid elements in the direction from which the particles impinge from the processing instrument 11, i.e. from the tubular magnetron. Depending on the magnitude of the working pressure, this correspondingly thin deposited layer, the thickness of which is predetermined by the width of the carrier elements, can also have a relatively pronounced porous structure. With a sufficiently intense coating process, the gradually forming layer begins to close the free space that is spanned by the line-shaped carrier elements. The working pressure in this module is, for example, in the range from 1·10⁻⁰³ mbar to about 5·10⁻⁰¹ mbar.

In module 47, the voids between the carrier elements are coated with the same material or with another material. This material is evaporated by using an electron beam evaporation device 11, as a result of which the produced evaporated particles of the material penetrate into the matrix- or lattice-shaped construction material 18 coated with a thin layer or coat it already to a small extent. In any event, the probability that the vapor stream 59 can completely penetrate the meandering matrix- or lattice-shaped construction material 18 is extremely small, an essentially close to zero.

The winding device 1 from FIG. 2 is again used as the transport system for the winding material, which performs a meandering movement of the matrix- or lattice-shaped construction material 18 in opposite directions, so that the electron beam evaporation device 11 can be used to fill the voids of the matrix- or lattice-shaped construction material 18. The electron beam evaporation device 11 is arranged below the stack of layers only because the electron beam is shot into a crucible in which the coating material is located, with the coating material evaporating from the crucible. The crucible thus represents the actual source. All additional devices, for example hollow cathodes, whose plasma activates the evaporation cloud, are not shown.

The working pressure range in which the electron beam vaporization device 11 operates is between 10⁻⁰⁵ mbar and 10⁻⁰¹ mbar. Depending on the specific pressure range, it is advisable to use a lock chamber 51, as shown schematically in FIG. 10b, or other connecting devices, such as roller locks or slit locks.

A coating process similar to a conventional film coating is carried out in module 48. Each side of the matrix- or lattice-shaped construction material 18 is coated on a respective large coating roller 56. In the case of FIG. 10b, the material to be deposited is evaporated with electron beam evaporator devices 11, resulting in the buildup of a layer composed of the evaporated material on both sides of the matrix- or lattice-shaped construction material 18. The working pressure range in module 48 is again between 10⁻⁰⁵ mbar and 10⁻⁰¹ mbar, but generally corresponds to that which prevails in module 47 when the same material is evaporated. For this reason, it is not necessary to install a connection device between module 47 and module 48 that performs a lock function. At best, a slit lock might be necessary under certain circumstances.

If the pressure value in take-up module 39 is high compared to module 48, it is advisable to install a lock chamber 51, as shown in FIG. 10b, in order to obtain a clean separation between module 48 and take-up module 39. If the pressure in the take-up module 39 corresponds approximately to that of the module 48, then other connecting devices, such as slit locks, are sufficient.

In order to be able to quickly close the voids with a material to be coated, in order to be able to carry out surface-covering coating with another material, the “reel-to-reel”-vacuum processing system 10, which is schematically shown in FIG. 11c, can be used.

The voids of the matrix- or lattice-shaped construction material 18 are closed with the aid of vacuum arc devices on the basis of thermal spraying methods. This process requires a correspondingly large amount of material to be deposited. Vacuum arc thermal spray technology enables deposition rates that meet this requirement. However, compared to other vacuum coating processes, the layer created by this coating process has a rather coarse structure, with the dimensions of the structural elements formed during the coating process reaching 10 μm. However, the with this coating technology, the voids can advantageously be closed relatively quickly.

For the vacuum arc spraying process, the matrix- or lattice-shaped construction material 18 is transported in the module 49 via a winding device 4 of the type used in FIG. 4b. The working pressure for vacuum arc spraying is between 10⁺⁰² mbar and 10⁺⁰³ mbar and is therefore a very high range compared to other vacuum coating processes. Since the working pressure in module 50 is typically in the range between 10⁻⁰⁵ mbar and 10⁻⁰¹ mbar, it is hence advisable to install a lock chamber 52 as a roller lock between module 49 and module 50, which can be pumped out separately. If a correspondingly large gas throughput is required in both chambers, it still proves to be necessary in most applications to install a lock chamber as a slit lock, as shown in FIG. 11c.

When a roller lock is installed as a lock chamber 52, various coating methods can then be used in the module 50, which are also used for foil coatings. By way of the example in FIG. 11c, both sides of the matrix- or lattice-shaped construction material 18 are coated using tubular magnetrons 11.

FIG. 12 shows a basic diagram of two variants of a layered structure on the line-shaped carrier elements of the matrix- or lattice-shaped construction material 18.

In FIG. 12, the matrix- or lattice-shaped construction material 18 is shown separately in the left area, which in the example consists of so-called weft threads 60 and warp threads 61, from which a fabric representing one form of the construction material is built up.

The middle part of FIG. 12 shows an effect produced by an unillustrated processing instrument 11 from one side of the matrix- or lattice-shaped construction material 18. The primary direction 16 of the processing instrument 11 is shown. The middle part of FIG. 12 shows a progression of the coating or a growth of the layers from top-to bottom.

As can be seen, the material to be coated begins to build up or adhere to the line-shaped carrier elements, which correspond here to a weft thread 60, of the matrix- or lattice-shaped construction material 18. When the coating time is sufficiently long, the entire three-dimensional free space that is spanned by the line-shaped and node-shaped carrier elements is covered, without filling the voids in the process.

The layer 62 starts to grow first on a line-shaped carrier element. This growth of the layer 62 is continued, for example, until the three-dimensional voids (for example meshes in woven fabrics) are increasingly covered. In the lower part of the middle illustration, the growth has progressed in such a way that the layer 62 expands over the next line-shaped carrier element of the matrix- or lattice-shaped construction material 18 without necessarily making contact with this additional carrier element. In the meantime, a separate layer 62 has formed on this additional carrier element. As can be seen in the lower part of the middle representation of FIG. 12, an overlap 63 of the layers 62 occurs, causing the voids of the matrix- or lattice-shaped construction material 18 to be covered.

The right-hand part of FIG. 12 shows the effect of two unillustrated processing instruments 11 operating from two sides on the matrix- or lattice-shaped construction material 18. A preferred direction 16 of the two processing instruments 11 is shown in each case, for example from above and from below the matrix- or lattice-shaped construction material 18. The progression of the structure of the layer 62 forming on the line-shaped carrier elements is again shown from top to bottom. In this case, two layers 62 are formed on each line-shaped carrier element, which corresponds here also to a weft thread 60. After the growth of the layers 62 progresses, this second variant also produces a covering 63.

Such a layer structure with a covering 63 can be achieved, for example, with the arrangements according to FIGS. 2, 3 and 8. A matrix- or lattice-shaped construction material 18 covered in this way can subsequently be further processed or coated using methods known from the prior art just like a film.

FIG. 13 shows a schematic diagram of filling voids of the matrix- or lattice-shaped construction material 18, which in the example consists of so-called weft threads 60 and warp threads 61. The voids are therefore the areas between the weft threads 60 and the warp threads 61.

Voids in the matrix- or lattice-shaped construction material 18 can be filled, for example, by using the arrangements according to FIG. 7.

As shown in FIG. 7, two processing instruments 11 are used here. In this case, a first processing instrument 11 is responsible for the actual effect, i.e. the material deposition. The second processing instrument 11, having the reference number 33 in FIG. 7, is intended to produce with its secondary flux 34 a second or secondary effect aligned in a secondary direction 35, which influences the usable flux 13 expanding in a first preferred direction 16 of the particles emitted by the processing instrument 11, i.e. their deposition on the matrix- or lattice-shaped construction material 18.

This effect causes the particles emitted by the processing instrument 11 to successively fill the void spanned by the exemplary line-shaped and node-shaped carrier elements of the matrix- or lattice-shaped construction material 18 of FIG. 13, wherein deposited particles adhere to the already attached particles or layers at different angles. In this case, the voids may also only be partially filled, as is illustrated in FIG. 13 by the remaining voids in the center of the meshes of the matrix- or lattice-shaped construction material 18.

### LIST OF REFERENCES

1 winding device; “reel-to-reel” system;
2 additional “reel-to-reel” system; winding device; winding system
3 additional “reel-to-reel” system; winding device; winding system
4 additional “reel-to-reel” system; winding device; winding system
5 arrangement
6 arrangement
7 winding device; arrangement
8 arrangement
9 “reel-to-reel” vacuum processing system
10 system configuration; “reel-to-reel” vacuum processing system
11 processing tool; process source;
11a ion source
11b planar magnetron
11c tubular magnetron
11d vacuum arc spray device
11e− electron beam evaporator
11f electron beam evaporation device
12 flux exit surface
13 usable flux; spatial extent
14 forbidden zone; forbidden spatial area
15 length of the extent of contained flux spread; flux expansion
16 primary direction; preferred direction; flux propagation
17 angle distribution
18 flexible substrate; matrix- or lattice-shaped construction material
19 winding direction
20 first roller group; roller system; cylinder group
21 second roller group; roller system; cylinder group
22 third roller group; roller system; cylinder group
23 larger cylinder; larger roller
24 smaller cylinder; smaller roller
25 distance; small distance; magnitude of the length
26 free regions
27 first free region
28 second free region
29 shielding plate
30 propagation of the flux Φ; extension of the flux Φ
31 angle
32 magnitude of direction of movement of the layer package of the winding material
33 influencing instrument; second processing tool; gas nozzle
34 secondary flux; second flux; flux
35 secondary direction; second direction; further preferred direction
36 distinctive angular distribution; angular distribution
37a first subassembly
37b second subassembly
38 unwind module
39 take-up module
40 processing module
41 pump nozzle
42 pumping system
43 ion processing module
44 module multi-layer coating using tube magnetron
45 coating module using vacuum arc spray devices
46 module coating using tubular magnetron at a flat angle
47 multi-layer coating module using an electron beam evaporator
48 module conventional film coating arrangement using an electron beam evaporator
49 Variant of coating module using vacuum arc spray devices
50 module conventional film coating arrangement using tube magnetron
51 lock chamber, roller lock
52 lock chamber, slit lock
53 left upper deflection roller
54 lower left deflection roller
55 adjacent upper deflection roller on the right
56 large coating drum
57 roller lock
58 slit lock
59 vapor flux
60 weft threads
61 warp threads
62 layer
63 overlap
64, 64′ first transport direction
65, 65′ second transport direction
66 third transport direction
67 fourth transport direction

1-15. (canceled)

16. A method for processing a flexible substrate (18) with a processing instrument (11) while being moved through an evacuable process area of a vacuum processing system, wherein the flexible substrate (18) is a flexible matrix- or lattice-shaped construction material, the method comprising the steps of:
transporting a first layer of the flexible substrate (18) in a first transport direction (64); and
transporting at least one second layer of the flexible substrate (18) parallel to and at a distance between 1 mm and 10 mm from the first layer of the flexible substrate (18) in a second transport direction (65) opposite the first transport direction (64) through a free region (26) in the evacuable process area;
wherein a usable flux (13) of the processing instrument (11) simultaneously penetrates the first and the second layer of the flexible substrate (18) while these layers are transported in opposite directions through the free region (26).

17. A method for processing a flexible substrate (18) with a processing instrument (11) while being moved through an evacuable process area of a vacuum processing system, wherein the flexible substrate (18) is a flexible matrix- or lattice-shaped construction material, the method comprising the steps of:
transporting a first layer of the flexible substrate (18) in a first transport direction (64′) through a first free region (27) and subsequently in a third transport direction (66) different from the first transport direction (64′) through a second free region (28);
deflecting and transporting at least one second layer of the flexible substrate (18) parallel to the first layer of the flexible substrate (18) in a fourth transport direction (67) opposite to the third transport direction (66) through the second free region (28) and subsequently in a second transport direction (65′) opposite to the first transport direction (64′) through the first free region (27) in the evacuable process area; and
wherein a usable flux (13) of the processing instrument (11) simultaneously penetrates the first and the second layer of the flexible substrate (18) carrying the first and the second layer of the flexible substrate (18) while these layers are transported in opposite directions through the first free region (27) and/or the second free region (28).

18. The method according to claim 17, wherein the flexible substrate (18) is deflected several times and is transported in at least four layers of the flexible substrate (18) having a distance therebetween of between 1 and 10 mm through the free region (26) or the free regions (27, 28).

19. The method according to claim 17, wherein an angle subtended between the first and the third transport direction (64′, 66) and between the second and the fourth transport direction (65′, 67) is in a range between greater than 0 degrees and less than 180 degrees.

20. The method according to claim 16, wherein the flexible substrate (18) is a construction material comprised of line-shaped and node-shaped carrier elements.

21. The method according to claim 20, wherein the line-shaped and node-shaped carrier elements are formed of weft threads (60) and warp threads (61).

22. The method according to claim 20, further comprising the step of subjecting the flexible substrate (18) to a coating process that creates an enveloping coating of the line-shaped and node-shaped carrier elements and/or fills voids in the flexible substrate (18).

23. The method according to claim 21, further comprising the step of growing a layer (62) by flux propagation (16) on at least one side of the processing instrument (11) in the direction of the flexible substrate (18), starting at the weft thread (60) of the flexible substrate (18) in such a way that voids of the flexible substrate (18) representing areas between weft threads (60) and warp threads (61), are covered.

24. The method according to claim 21, wherein voids in the flexible substrate (18) representing areas between the weft threads (60) and the warp threads (61) are filled by using the processing instrument (11) having the usable flux (13) in cooperation with an influencing instrument (33) having a secondary flux (34).

25. A vacuum processing system for processing a flexible substrate (18), wherein the vacuum processing system comprises at least one unwind module (38), a take-up module (39) and an evacuatable process area arranged between these modules (38, 39) with a processing instrument (11), the system comprising:
a first group of rollers (20) and a second group of rollers (21) are arranged, that in each group of rollers (20, 21) there are arranged several rollers (24) having a first diameter and several rollers (23) having a second diameter larger the first diameter for deflecting the flexible substrate (18), that at least one free region (26) with the processing instrument (11) is arranged between the first group of rollers (20) and the second group of rollers (21), through which the flexible substrate (18) is transported in opposite directions without a change of direction, and wherein the groups of rollers (20, 21) are arranged so that the flexible substrate (18) is transported in opposite directions in at least two layers having a spacing therebetween of between 1 mm and 10 mm in a first transport direction (64) and a second transport direction (65).

26. A vacuum processing system for processing a flexible substrate (18), the vacuum processing system having at least one unwind module (38), a take-up module (39) and an evacuatable process area arranged between these modules (38, 39) with at least one processing instrument (11), the system comprising:
a first group of rollers (20), a second group of rollers (21) and a third group of rollers (22) arranged so that a first free region (27) is between the first group of rollers (20) and the third group of rollers (22) and a second free region (28) is between the second group of rollers (21) and the third group of rollers (22), wherein the groups of rollers (20, 21, 22) are arranged so that the flexible substrate (18) is transported in at least two layers having a spacing therebetween of between 1 mm and 10 mm in opposite directions and without a change in direction through the first free region (27) and the second free region (28), the at least one processing instrument (11) being arranged in the free regions (27, 28).

27. The vacuum processing system according to claim 25, wherein in the free region (26) a first processing instrument (11) is arranged above a first side of the layers of the flexible substrate (18) having a spacing therebetween of between 1 mm and 10 mm and moving in opposite directions and a further second processing instrument (11) is arranged above a second side, opposite the first side, of the layers of the flexible substrate (18) having a spacing therebetween of between 1 mm and 10 mm and moving in opposite directions.

28. The vacuum processing system according to claim 25, wherein in the free region (26) a first processing instrument (11) is arranged above a first side of the layers of the flexible substrate (18) having a spacing therebetween of between 1 mm and 10 mm and moving in opposite directions and a further second processing instrument (33) is arranged above the same side of the layers of the flexible substrate (18) having a spacing therebetween of between 1 mm and 10 mm and moving in opposite directions, wherein the first processing instrument (11) has a preferred direction (16) oriented at an angle α with respect to a surface of the flexible substrate (18) and the second processing instrument (33) has a preferred direction (35) with an angle different from the angle α with respect to the surface of the flexible substrate (18).

29. The vacuum processing system according to claim 25, wherein the processing instrument (11) has an ion source (11a), a planar magnetron (11b), a tubular magnetron (11c), a vacuum arc spray device (11d), an electron beam evaporator (11e), an electron beam evaporation device (11f) or an arc evaporation device.

30. The method according to claim 16, wherein the at least one second layer of the flexible substrate (18) is at a distance 2.5 mm from the first layer of the flexible substrate (18).

31. The method according to claim 18, wherein the at least four layers of the flexible substrate (18) are parallel and the distance therebetween is 2.5 mm.

32. The method according to claim 17, wherein the flexible substrate (18) is a construction material comprised of line-shaped and node-shaped carrier elements.

33. The method according to claim 32, wherein the line-shaped and node-shaped carrier elements are formed of weft threads (60) and warp threads (61).

34. The method according to claim 32, further comprising the step of subjecting the flexible substrate (18) to a coating process that creates an enveloping coating of the line-shaped and node-shaped carrier elements and/or fills voids in the flexible substrate (18).

35. The vacuum processing system according to claim 25, wherein the at least two layers of the flexible substrate (18) are mutually parallel and the spacing therebetween is 2.5 mm.

36. The vacuum processing system according to claim 26, wherein the at least two layers of the flexible substrate (18) are mutually parallel and the spacing therebetween is 2.5 mm.

37. The vacuum processing system according to claim 26, wherein in the free region (27, 28) a first processing instrument (11) is arranged above a first side of the layers of the flexible substrate (18) having a spacing therebetween of between 1 mm and 10 mm and moving in opposite directions and a further second processing instrument (11) is arranged above a second side, opposite the first side, of the layers of the flexible substrate (18) having a spacing therebetween of between 1 mm and 10 mm and moving in opposite directions.

38. The vacuum processing system according to claim 26, wherein in the free region (27, 28) a first processing instrument (11) is arranged above a first side of the layers of the flexible substrate (18) having a spacing therebetween of between 1 mm and 10 mm and moving in opposite directions and a further second processing instrument (33) is arranged above the same side of the layers of the flexible substrate (18) having a spacing therebetween of between 1 mm and 10 mm and moving in opposite directions, wherein the first processing instrument (11) has a preferred direction (16) oriented at an angle α with respect to a surface of the flexible substrate (18) and the second processing instrument (33) has a preferred direction (35) with an angle different from the angle α with respect to the surface of the flexible substrate (18).

39. The vacuum processing system according to claim 26, wherein the processing instrument (11) has an ion source (11a), a planar magnetron (11b), a tubular magnetron (11c), a vacuum arc spray device (11d), an electron beam evaporator (11e), an electron beam evaporation device (11f) or an arc evaporation device.
